(19) United States
(12) Patent Application Publication
(10) Pub. No.: US 2025/0140740 A1
(43) Pub. Date: May 1, 2025

(54) METHOD OF MANUFACTURING SEMICONDUCTOR DEVICE

(71) Applicant: Renesas Electronics Corporation, Tokyo (JP)

(72) Inventors: Ryusei TAKAISHI, Tokyo (JP); Koichi HASEGAWA, Tokyo (JP)

(21) Appl. No.: 18/921,312

(22) Filed: Oct. 21, 2024

(30) Foreign Application Priority Data
Oct. 26, 2023 (JP) 2023-184134

(51) Int. Cl. H01L 23/00

(52) U.S. Cl. CPC H01L 24/85; H01L 2224/85123

(57) ABSTRACT

A method of manufacturing a semiconductor device includes, after a wire bonding step, a step of determining a quality as to whether or not a whole of an end portion of a wire is located within a bonding region. A semiconductor chip includes a plurality of position determining opening patterns arranged in a region located around a main opening portion including the bonding region in plan view. The bonding region has a rectangular shape having an area smaller than an opening area of the main opening portion in plan view. The bonding region is defined by the plurality of position determining opening patterns.

### CROSS-REFERENCE TO RELATED APPLICATIONS

The disclosure of Japanese Patent Application No. 2023-184134 filed on Oct. 26, 2023 including the specification, drawings and abstract is incorporated herein by reference in its entirety.

### BACKGROUND

The present invention relates to a semiconductor device and a method of manufacturing the same.

There are disclosed techniques listed below.
[Patent Document 1] Japanese Unexamined Patent Application Publication No. H2-90634

Patent Document 1 discloses a technique related to a semiconductor device including a bonding pad having an alignment mark formed of a slit or a protrusion corresponding to a positioning cross mark of a wire bonder.

### SUMMARY

One of performance indices required for semiconductor devices is reliability. Reliability of a semiconductor device is ability of the semiconductor device to continue to perform a function defined in advance in specifications or the like for a predefined period.

For example, there is a semiconductor device in which a wire is connected to a pad formed on a main surface of a semiconductor chip. In this semiconductor device, characteristic fluctuation may occur due to misalignment of a bonding position at which a wire is connected.

If the misalignment of bonding position can be quickly detected, semiconductor devices in which characteristic fluctuation has occurred due to the misalignment can be selectively excluded. As a result, only semiconductor devices in which misalignment is within an allowable range, that is, only reliable semiconductor devices, can be selected as non-defective products.

Other problems and novel features will become apparent from the description of this specification and the accompanying drawings.

A method of manufacturing a semiconductor device according to an embodiment includes, after a wire bonding step, a step of determining a quality as to whether or not a whole of a bonding portion of the wire is located within a bonding region. A semiconductor chip includes a plurality of position determining opening patterns arranged in a region located around a main opening portion including the bonding region. The bonding region has a rectangular shape having an area smaller than an opening area of the main opening portion in plan view. The bonding region is defined by the plurality of position determining opening patterns and the second position determining opening pattern.

A semiconductor device according to another embodiment includes a main surface, a pad formed on the main surface, an insulating film in which an opening portion for exposing a part of the pad is formed, and a plurality of position determining opening patterns arranged in a region located around a main opening portion in plan view. The plurality of position determining opening patterns includes a first position determining opening pattern arranged at a position closest to a first corner portion among the first corner portion, the second corner portion, the third corner portion, and the fourth corner portion of the main opening portion and a second position determining opening pattern arranged at a position closest to the third corner portion or the fourth corner portion among the first corner portion, the second corner portion, the third corner portion, and the fourth corner portion of the main opening portion.

According to the above embodiment, performance of the semiconductor device can be improved.

### BRIEF DESCRIPTION OF THE DRAWINGS

FIG. 1 is a diagram illustrating a circuit configuration example of a semiconductor device including a power transistor and a control circuit that controls the power transistor.

FIG. 2 is a transparent plan view illustrating an example of structure of the semiconductor device illustrated in FIG. 1.

FIG. 3 is a cross-sectional view taken along line A-A of FIG. 2.

FIG. 4 is a flowchart illustrating an example of a manufacturing process of the semiconductor device illustrated in FIGS. 1 to 3.

FIG. 5 is an enlarged plan view illustrating a part of a lead frame prepared in a lead frame preparing step illustrated in FIG. 4.

FIG. 6 is a plan view (top view) of a semiconductor chip prepared in a semiconductor chip preparing step of FIG. 4.

FIG. 7 is a plan view (top view) of a semiconductor chip different from that in FIG. 6 prepared in the semiconductor chip preparing step of FIG. 4.

FIG. 8 is an enlarged cross-sectional view taken along line B-B of FIG. 6.

FIG. 9 is an explanatory view illustrating an example of detailed steps of a wire bonding step illustrated in FIG. 4.

FIG. 10 is an explanatory view schematically illustrating a configuration example of a wire bonding device used in the wire bonding step illustrated in FIG. 4.

FIG. 11 is an enlarged cross-sectional view illustrating a first bonding step of a wire forming step.

FIG. 12 is a plan view schematically illustrating operation of a wedge tool in a bent portion forming step of the wire forming step.

FIG. 13 is an explanatory diagram illustrating an example of an image displayed on a monitor at a time of “teaching” performed in an identifying step of a bonding region of FIG. 9.

FIG. 14 is an explanatory diagram illustrating an example of an image displayed on the monitor in a quality determining step illustrated in FIG. 4.

FIG. 15 is an explanatory diagram illustrating details of the quality determining step illustrated in FIG. 4.

FIG. 16 is an enlarged plan view illustrating a region around a main opening portion of a semiconductor chip, which is a modification of FIG. 13.

FIG. 17 is an enlarged cross-sectional view taken along line C-C of FIG. 6.

FIG. 18 is an enlarged cross-sectional view illustrating a modification of FIG. 17.

FIG. 19 is an enlarged plan view illustrating another modification of FIG. 13.

FIG. 20 is an enlarged plan view illustrating another modification of FIG. 13.

FIG. 21 is an enlarged plan view illustrating another modification of FIG. 13.

FIG. 22 is a block diagram illustrating a configuration example of a determination unit illustrated in FIG. 10.

### DETAILED DESCRIPTION

<Explanation of Description Form, Basic Terminology, and Usage in this Application>

In this application, the embodiment will be described in a plurality of sections or the like when required as a matter of convenience. However, these sections or the like are not irrelevant to each other and serve as each part of a single example unless otherwise stated, and a part of one example relates to the other example as details or a part of the entire of a modification regardless of the order of description. Also, the repetitive description of similar parts will be omitted in principle. Further, the constituent elements in the embodiment are not always indispensable unless otherwise stated or except for the case where the constituent elements are theoretically limited to that number or the constituent elements are obviously indispensable from the context.

Likewise, in the description of the embodiment or the like, the phrase “X made of A” for a material, a composition or the like is not intended to exclude those containing elements other than A unless otherwise specified or except for the case where it is clearly not so from the context. For example, as for a component, it means “X containing A as a main component”. For example, a “silicon member” or the like is not limited to pure silicon and it is obvious that the silicon member includes a member made of silicon germanium (SiGe) alloy, a member made of multicomponent alloy containing silicon as a main component, and a member containing other additives or the like. In addition, when mentioning gold plating, a Cu layer, nickel plating or the like, it includes a member containing gold, Cu, nickel, or the like as a main component as well as a pure one unless otherwise specified clearly.

In addition, when referring to a specific value or amount, a value or amount larger or smaller than the specific value or amount is also applicable unless otherwise stated or except for the case where the value or amount is logically limited to the specific value or amount and the value or amount is apparently limited to the specific value or amount from the context.

Further, in the drawings for the embodiment, the same or similar parts are denoted by the same or similar reference characters or reference numbers, and the descriptions thereof are not repeated in principle.

In addition, in the accompanying drawings, hatching may be omitted even in cross-sections in the case where the hatchings make the drawings complicated on the contrary or discrimination from void is clear. In relation to this, when it is clear from the description or the like, an outline of a background may be omitted even for a planarly closed hole. Furthermore, even in the cases other than the cross-section, hatching or dot pattern may be applied so as to clarify that a portion is not a vacant space or clearly illustrate the boundary between regions.

In the embodiments described below, a semiconductor device referred to as a power device or a power semiconductor device incorporated in a power control circuit such as a power supply circuit will be described as an example of the semiconductor device. The semiconductor device described below is incorporated in a power conversion circuit and functions as a switching element. In addition, a transistor incorporated in a switching circuit for power conversion or the like is referred to as a power transistor.

### <Configuration Example of Power Transistor and Control Circuit>

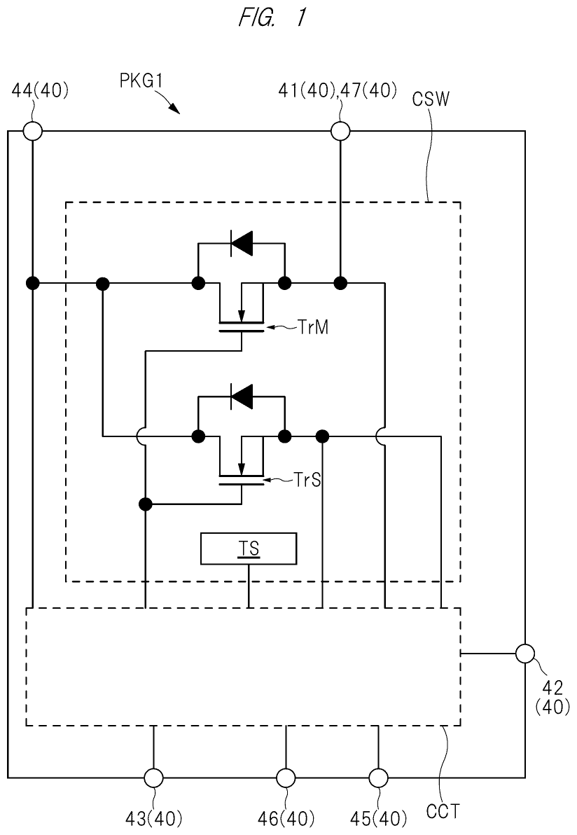

FIG. 1 is a diagram illustrating a circuit configuration example of a semiconductor device including a power transistor and a control circuit that controls the power transistor. The power transistor illustrated in FIG. 1 is, for example, a power metal-oxide-semiconductor field-effect transistor (MOSFET).

As the power transistor, a modification may be applied instead of the power MOSFET. For example, the technique described below can be widely applied to a semiconductor device using an insulated-gate bipolar transistor (IGBT) as a power transistor. In this case, a “source” described below is applied while being replaced with an “emitter”.

In FIG. 1, a semiconductor device PKG1 includes a switching circuit CSW and a control circuit CCT. The switching circuit CSW includes a main transistor TrM, which is the power transistor, a sense transistor Trs, and a temperature sensor TS.

In the switching circuit CSW, the main transistor TrM is provided between a lead 44, which is a power supply terminal for supplying a power supply potential, and a lead 41 (or a lead 47), which is an output terminal. The main transistor TrM functions as a switching element for turning on and off a current flowing between the power supply terminal and the output terminal.

On the other hand, the sense transistor TrS has a function of detecting a current value of the current flowing through the main transistor TrM. In addition, the temperature sensor TS has a function of detecting a temperature of the switching circuit CSW.

Further, the control circuit CCT has a function of controlling the switching circuit CSW. The control circuit CCT includes, for example, a pre-driver that applies a gate voltage to a gate electrode of the main transistor TrM and a gate electrode of the sense transistor TrS. In FIG. 1, the control circuit CCT is electrically connected to a lead 43 and a lead 46, which are input terminals of the semiconductor device PKG1, a lead 42, which is a ground terminal, and a lead 45, which is an output terminal for outputting an output of the control circuit CCT to the outside of the semiconductor device PKG1.

The control circuit CCT is configured to control on and off of the main transistor TrM included in the switching circuit CSW based on a control signal input from the lead 43. That is, the control circuit CCT controls on and off of the main transistor TrM by switching the gate voltage applied to the gate electrode of the main transistor TrM. By controlling on and off of the main transistor TrM in this way, it is possible to control a current supplied from the lead 41, which is the output terminal electrically connected to a source of the main transistor TrM, to a load connected to the outside of the semiconductor device PKG1.

### <Semiconductor Device>

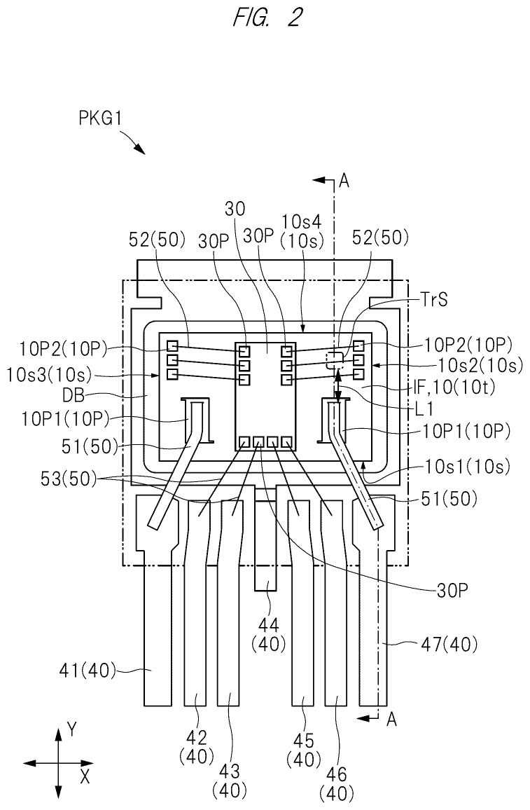

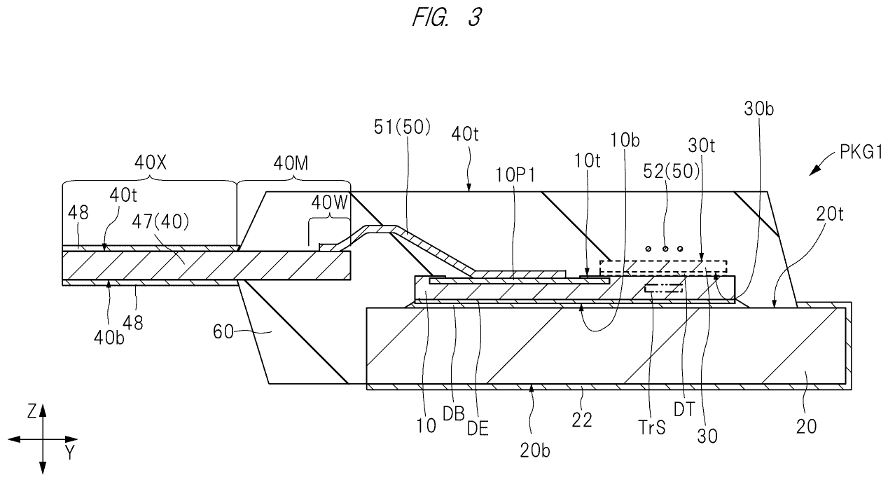

Next, an example of structure of the semiconductor device PKG1 illustrated in FIG. 1 will be described. FIG. 2 is a transparent plan view illustrating the example of the structure of the semiconductor device illustrated in FIG. 1. FIG. 3 is a cross-sectional view taken along line A-A of FIG. 2. Note that, in order to illustrate an example of a layout of components of the semiconductor device PKG1, the semiconductor device PKG1 is illustrated in a transparent plan view in which the semiconductor device PKG1 is seen through a sealing body 60 illustrated in FIG. 3. In addition, although a semiconductor chip 30 illustrated in FIG. 2 is not present in a cross-section taken along line A-A of FIG. 2, FIG. 3 indicates an outline of the semiconductor chip 30 and an insulating adhesive DT for bonding and fixing the semiconductor chip 30 onto the semiconductor chip 10 by dotted lines. Furthermore, FIGS. 2 and 3 indicate a position where the sense transistor TrS illustrated in FIG. 1 is formed by a dash-dot-dot line.

FIGS. 2 and 3 illustrate any of an X direction (see FIG. 2), a Y direction, and a Z direction (see FIG. 3). The Y direction is a side intersecting the X direction, and the X direction and the Y direction are perpendicular to each other in the following description. The Z direction is a direction perpendicular to each of the X direction and the Y direction. In other words, the Z direction is a normal direction with respect to an X-Y plane including the X direction and the Y direction. In the following description, “thickness” refers to the length in the Z direction in principle. Further, in the following description, “plan view” refers to plan view in which the X-Y plane is viewed in principle.

As illustrated in FIGS. 2 and 3, the semiconductor device PKG1 according to the present embodiment includes a semiconductor chip 10, a die pad (a metal plate, a chip mounting portion, or a heat sink) 20 on which the semiconductor chip 10 is mounted, a semiconductor chip 30 (see FIG. 2) mounted on the semiconductor chip 10, a plurality of leads (terminals) 40 as external terminals, and a plurality of wires 50.

As illustrated in FIG. 3, the semiconductor device PKG1 further includes the sealing body 60. Each of the semiconductor chip 10, the semiconductor chip 30, and the plurality of wires 50 is sealed by the sealing body 60. In addition, the semiconductor chip 10, an upper surface 20t of the die pad 20, and inner lead portions (sealed portions) 40M (see FIG. 3) of the plurality of leads 40 are sealed by the sealing body 60.

The die pad 20 has an upper surface (surface) 20t and a lower surface 20b on a side opposite the upper surface 20t. The die pad 20 is a chip mounting member for mounting the semiconductor chip 10. In the example illustrated in FIG. 3, the lower surface 20b of the die pad 20 is exposed from the sealing body 60. The lower surface 20b of the die pad 20 exposed from the sealing body 60 is covered with a metal film 22. The metal film 22 is made of, for example, solder. In the present embodiment, as illustrated in FIG. 2, the die pad 20 is connected to one (lead 44) of the plurality of leads 40. More specifically, the lead 44 is formed integrally with the die pad 20.

The semiconductor chip 10 is mounted on the upper surface 20t of the die pad 20 via a die bond material DB. The semiconductor chip 10 includes a power transistor (in the present embodiment, the main transistor TrM illustrated in FIG. 1).

As illustrated in FIG. 3, the semiconductor chip 10 has an upper surface (a main surface, a front surface, or a surface) 10t and a lower surface (a main surface, a back surface, or a surface) 10b on a side opposite the upper surface 10t. As illustrated in FIG. 2, the semiconductor chip 10 has four sides (chip sides) 10s in plan view. The four sides 10s include a side 10s1 extending in the X direction, a side 10s2 intersecting the side 10s1 and extending in the Y direction intersecting the X direction, a side 10s3 extending in the Y direction and located on a side opposite the side 10s2, and a side 10s4 extending in the X direction and located on a side opposite the side 10s1. The side 10s1 is a side that is arranged at a position closest to each of the plurality of leads 40 among the four sides 10s of the semiconductor chip 10 and extends in the X direction. In the example illustrated in FIG. 2, the semiconductor chip 10 has a rectangular shape in plan view, and is arranged such that the side 10s1 and the side 10s4, which are long sides, extend along the X direction.

As illustrated in FIG. 2, the semiconductor chip 10 includes a plurality of pads (electrodes or electrode pads) 10P. A part of each of the plurality of pads 10P is exposed from an insulating film IF of the semiconductor chip 10 described later on the upper surface 10t of the semiconductor chip 10.

The plurality of pads 10P includes a source pad 10P1 connected to the source of the power transistor. In the example illustrated in FIG. 2, parts of the source pad 10P1 are exposed from the insulating film IF at two places on the upper surface 10t. The source pad 10P1 is connected to the lead 40 (the lead 41 or the lead 47 in the example illustrated in FIG. 2) via a wire 51. A detailed structure around the source pad 10P1 will be described later.

The plurality of pads 10P includes a plurality of pads 10P2 electrically connected to the semiconductor chip 30 via wires 52. The plurality of pads 10P2 includes a gate pad connected to the gate of the power transistor. Also, at least some of the plurality of pads 10P2 is electrically connected to the sense transistor TrS. Further, some of the plurality of pads 10P2 is electrically connected to the temperature sensor TS illustrated in FIG. 1.

As illustrated in FIG. 2, among the plurality of pads 10P, the exposed area of the source pad 10P1 is larger than that of the other pads 10P2. More specifically, each of the source pad 10P1 and the other pads 10P2 is exposed from the insulating film IF in opening portions formed in the insulating film IF. The opening area of the opening portion in which the source pad 10P1 is exposed from the insulating film IF is larger than that of the opening portions in which the other pads 10P2 are exposed from the insulating film IF.

The source pad 10P1 constitutes a current path through which a larger current flows as compared with the other pads 10P2. From a viewpoint of increasing the cross-sectional area of the path through which a large current flows and reducing a resistance value, it is preferable that wires having a wire diameter larger than that of the other wires 52 are used as the wires 51 connected to the source pad 10P1. In addition, from a viewpoint of reducing resistance of a joint portion between the wire 51 and the source pad 10P1, it is preferable to increase the area of the joint portion between the wire 51 and the source pad 10P1. Therefore, the exposed area of the source pad 10P1 is preferably large.

As illustrated in FIG. 3, the semiconductor chip 10 includes a drain electrode DE formed on the lower surface 10b. In the present embodiment, as described above, the die pad 20 is connected to one (lead 44) of the plurality of leads 40. Furthermore, the die bond material DB is made of solder or a conductive resin (for example, a so-called silver paste), and the die pad 20 is electrically connected to the drain electrode DE. Therefore, in the case of the semiconductor device PKG1, the die pad 20 can be used as a current path. Even if a large current flows, a resistance value of a current path connected to a drain of the power transistor can be reduced by using the drain electrode DE formed on the entire lower surface 10b of the semiconductor chip 10 and the die pad 20 as the current path.

As illustrated in FIGS. 2 and 3, the semiconductor chip 30 is mounted on the upper surface 10t of the semiconductor chip 10. The semiconductor chip 30 is bonded and fixed onto the upper surface 10t of the semiconductor chip 10 via the insulating adhesive DT (see FIG. 3).

The semiconductor chip 30 includes the control circuit CCT (see FIG. 1) that controls the power transistor (the main transistor TrM illustrated in FIG. 1).

In the example illustrated in FIG. 2, the semiconductor chip 30 is arranged between two opening portions for the source pad 10P1 in plan view. In addition, in the example illustrated in FIG. 2, a position where the semiconductor chip 30 is mounted includes the center of the upper surface 10t in plan view.

The semiconductor chip 30 includes a plurality of pads (electrodes or electrode pads) 30P. Some of the plurality of pads 30P (a plurality of pads 30P2 illustrated in FIG. 7, which will be described later) are electrically connected to the pads 10P2 of the semiconductor chip 10 via the wires 52. Others of the plurality of pads 30P (a plurality of pads 30P3 illustrated in FIG. 7, which will be described later) are connected to the leads 40 (in the example illustrated in FIG. 2, the lead 42, the lead 43, the lead 45, and the lead 46) via the wires 53.

As illustrated in FIG. 3, the semiconductor chip 30 has an upper surface (a main surface, a front surface, or a surface) 30t and a lower surface (a main surface, a back surface, or a surface) 30b on a side opposite the upper surface 30t.

The plurality of leads 40 is arranged along the side 10s1 extending along the X direction among the plurality of sides 10s of the semiconductor chip 10. Each of the plurality of leads 40 is connected to the semiconductor chip 10 or the semiconductor chip 30 via the wire 50.

As illustrated in FIG. 3, each of the plurality of leads 40 illustrated in FIG. 2 includes an inner lead portion 40M sealed by the sealing body 60 and an outer lead portion (an outer portion or an exposed portion) 40X exposed from the sealing body 60.

Each of the plurality of leads 40 has an upper surface 40t and a lower surface 40b. Each of the upper surface 40t of the outer lead portion 40X and the lower surface 40b of the outer lead portion 40X is covered with a metal film 48. The metal film 48 is made of, for example, solder.

The plurality of wires 50 illustrated in FIG. 2 includes the wires 51 connected to the source pad 10P1 of the semiconductor chip 10 and the leads 41 and 47. One end of each of the plurality of wires 51 is connected to the corresponding source pad 10P1 and the other end thereof is connected to a wire bonding portion 40W (see FIG. 3) of the lead 41 (or the lead 47). The wires 51 are made of, for example, aluminum. The wires 51 have a wire diameter greater than that of the other wires 50 (the wires 52 and the wires 53). In other words, the wires 51 are wider than the other wires 50 (the wires 52 and the wires 53). Note that the width of the wires 50 mentioned here is the length in a direction perpendicular to a direction in which the wires 50 extend.

The plurality of wires 50 includes the plurality of wires 52 connected to the pads 10P2 of the semiconductor chip 10 and the pads 30P of the semiconductor chip 30. One end of each of the plurality of wires 52 is connected to the corresponding pad 10P2 and the other end thereof is connected to the corresponding pad 30P.

The plurality of wires 50 includes the plurality of wires 53 connected to the pads 30P of the semiconductor chip 30 and one of the leads 42, 43, 45, and 46. One end of each of the plurality of wires 53 is connected to the corresponding pad 30P and the other end thereof is connected to the wire bonding portion 40W (see FIG. 3) of one of the leads 42, 43, 45, and 46.

Signal currents such as a control signal current and a signal current output from the sense transistor TrS flow through the wires 52 and the wires 53. Therefore, since values of the currents flowing through the wires 52 and the wires 53 are smaller than those of the wires 51, wires 50 having a wire diameter smaller than that of the wire 51 are used as the wires 52 and the wires 53.

The sealing body 60 is mainly made of, for example, a thermosetting resin such as an epoxy resin. In addition, in the present embodiment, in order to improve characteristics (for example, expansion characteristics due to a thermal effect) of the sealing body 60, for example, filler particles such as silica (silicon dioxide; SiO₂) particles are mixed in a resin material.

### <Method of Manufacturing Semiconductor Device>

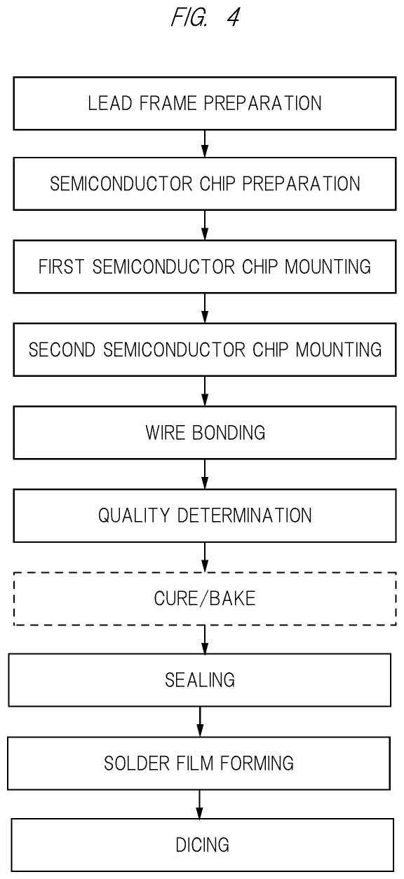

Next, a method of manufacturing the semiconductor device illustrated in FIGS. 1 to 3 will be described. FIG. 4 is a flowchart illustrating an example of a manufacturing process of the semiconductor device illustrated in FIGS. 1 to 3. In the example illustrated in FIG. 4, the method of manufacturing a semiconductor device according to the present embodiment includes a lead frame preparing step, a semiconductor chip preparing step, a first semiconductor chip mounting step, a second semiconductor chip mounting step, a wire bonding step, a quality determining step, a sealing step, a solder film forming step, and a dicing step.

### <Lead Frame Preparing Step>

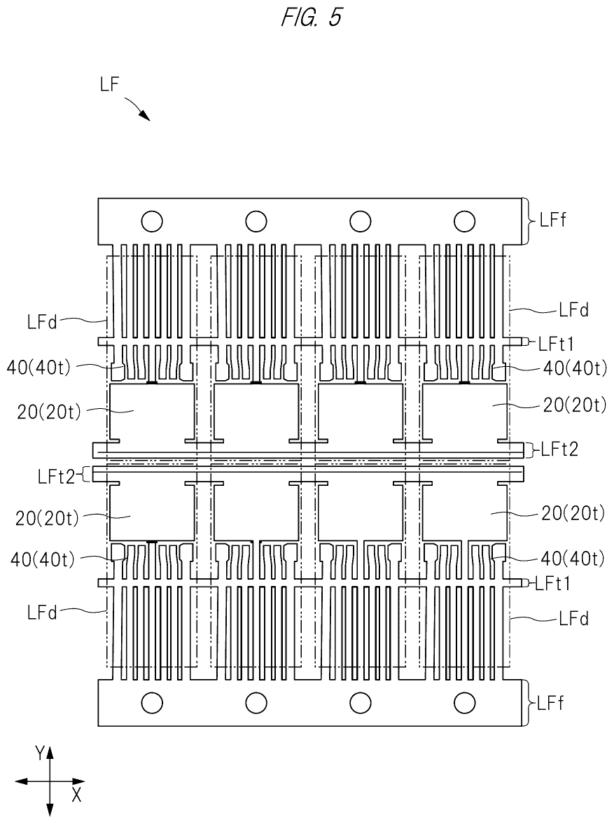

First, in the lead frame preparing step illustrated in FIG. 4, a lead frame LF illustrated in FIG. 5 is prepared. FIG. 5 is an enlarged plan view illustrating a part of the lead frame prepared in the lead frame preparing step illustrated in FIG. 4.

As illustrated in FIG. 5, the lead frame LF prepared in this step includes a plurality of device forming portions LFd connected to frame portions LFf. FIG. 5 illustrates eight device forming portions LFd. Each of the plurality of device forming portions LFd corresponds to one semiconductor device PKG1 illustrated in FIG. 1. The lead frame LF is a so-called multi-piece base material in which the plurality of device forming portions LFd is arranged in a matrix. Since a plurality of semiconductor devices PKG1 (see FIG. 1) can be collectively manufactured by using the lead frame LF including the plurality of device forming portions LFd as described above, manufacturing efficiency can be improved.

The lead frame LF is made of, for example, a metal material containing copper (Cu) as a main component. Each of the plurality of device forming portions LFd is connected to the corresponding frame portion LFf. The frame portions LFf are support portions that support each of members formed in the device forming portions LFd until the dicing step illustrated in FIG. 4.

The die pads 20 and the plurality of leads 40 illustrated in FIG. 3 are formed in the device forming portions LFd. The die pads 20 are connected to the corresponding frame portions LFf via one of the plurality of leads 40 and supported by the frame portions LFf. Each of the plurality of leads 40 is connected to the corresponding frame portion LFf and supported by the frame portion LFf.

Focusing on one of the plurality of device forming portions LFd, this step can be expressed as a step of preparing a die pad having an upper surface 20t, that is, a die pad preparing step.

In addition, the plurality of leads 40 is connected to each other via corresponding tie bars LFt1. In the example illustrated in FIG. 5, the plurality of die pads 20 is connected to each other via corresponding tie bars LFt2. As illustrated in FIG. 5, the tie bars LFt2 are arranged on a side opposite the plurality of leads 40 via the die pads 20 in the device forming portions LFd.

Note that FIG. 5 illustrates an example of the lead frame, and there are various modifications of a shape of the lead frame. For example, in the example illustrated in FIG. 5, each of the plurality of leads 40 is connected to the corresponding frame portion LFf. In other words, the plurality of die pads 20 is arranged at positions farther from the corresponding frame portions LFf than the plurality of leads 40 is. As a modification of the lead frame illustrated in FIG. 5, there is a case where a frame portion LFf is arranged between device forming portions LFd adjacent to each other in the Y direction. In this case, in the Y direction, a plurality of leads 40 of a first device forming portion LFd is connected to one side of the frame portion LFf, and a plurality of leads 40 of a second device forming portion LFd is connected to the other side of the frame portion LFf (a side opposite the above-mentioned one side in the Y direction). In this case, the tie bars LFt2 are provided at positions of the frame portions LFf illustrated in FIG. 5, and the plurality of device forming portions LFd is arranged between the two tie bars LFt2.

### <Semiconductor Chip Preparing Step>

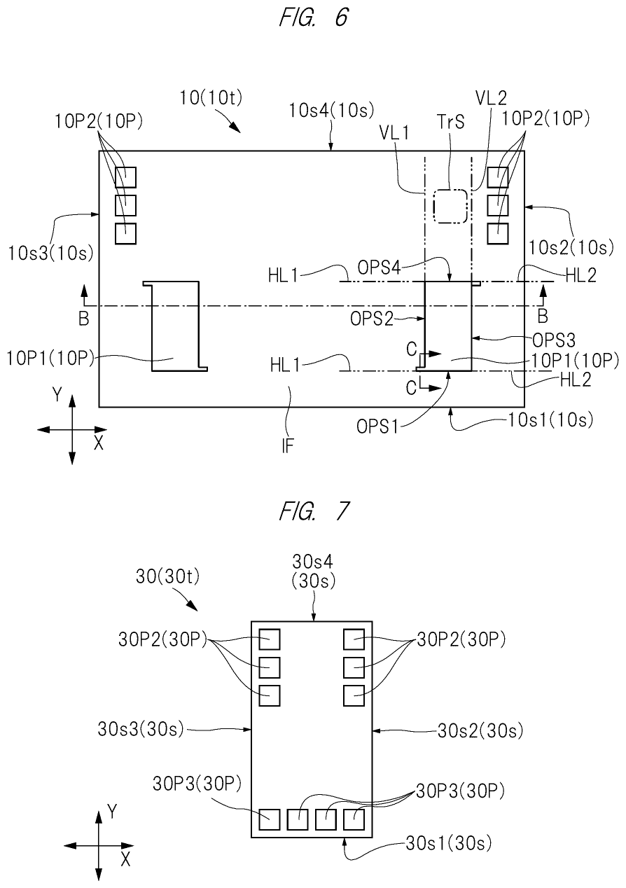

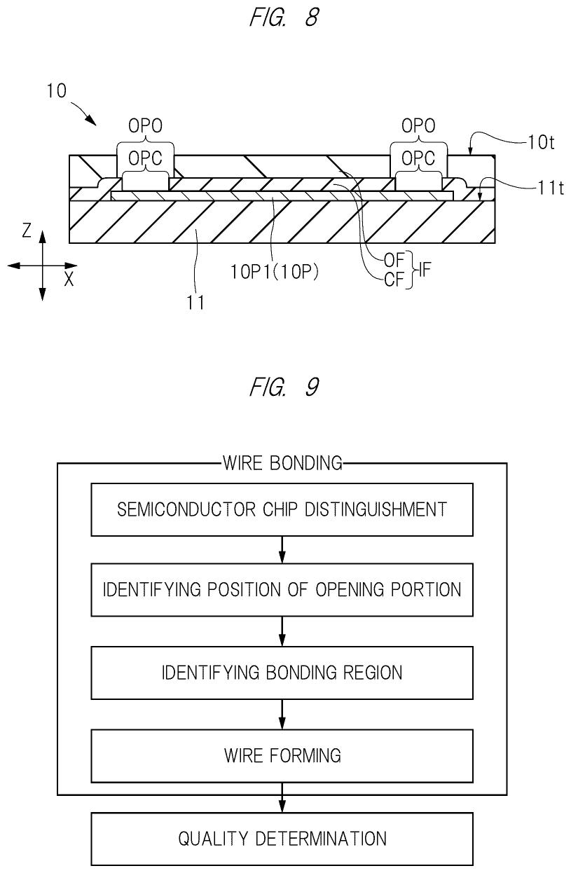

In the semiconductor chip preparing step illustrated in FIG. 4, the semiconductor chip 10 illustrated in FIG. 6 and the semiconductor chip 30 illustrated in FIG. 7 are prepared. Each of FIGS. 6 and 7 is a plan view (top view) of the semiconductor chip prepared in the semiconductor chip preparing step of FIG. 4. FIG. 8 is an enlarged cross-sectional view taken along line B-B of FIG. 6.

With regard to the semiconductor chip 10 illustrated in FIG. 6 and the semiconductor chip 30 illustrated in FIG. 8, redundant description will be omitted. Also, in FIG. 6, an extended line VL1 of a side OPS2 and an extended line VL2 of a side OPS3 of an opening portion where a part of the source pad 10P1 is exposed are indicated by dash-dot-dot lines. Further, in FIG. 6, extended lines (extended lines HL1 and extended lines HL2) of a side OPS1 and a side OPS4 are indicated by dash-dot-dot lines. These will be described later.

As illustrated in FIG. 7, the semiconductor chip 30 has four sides (chip sides) 30s in plan view. The four sides 30s include a side 30s1 extending in the X direction, a side 30s2 intersecting the side 30s1 and extending in the Y direction intersecting the X direction, a side 30s3 extending in the Y direction and located on a side opposite the side 30s2, and a side 30s4 extending in the X direction and located on a side opposite the side 30s1. The side 30s1 is a side that is arranged at a position closest to each of the plurality of leads 40 illustrated in FIG. 2 among the four sides 30s of the semiconductor chip 30 and extends in the X direction. In the example illustrated in FIG. 7, the semiconductor chip 30 has a rectangular shape in plan view, and is arranged such that the side 30s2 and the side 30s3, which are long sides, extend along the Y direction.

As illustrated in FIG. 8, the semiconductor chip 10 includes a main surface 11t, a pad 10P (for example, the source pad 10P1) formed on the main surface 11t, and the insulating film IF formed on the main surface 11t.

In the example illustrated in FIG. 8, an upper surface of an insulating layer 11, which is a base layer of the source pad 10P1, corresponds to the main surface 11t. The insulating layer 11 is formed on a main surface of a semiconductor substrate. The insulating layer 11 is composed of, for example, silicon oxide. Although not illustrated, each of the plurality of pads 10P2 illustrated in FIG. 6 is formed on the insulating layer 11. In addition, the semiconductor chip 30 illustrated in FIG. 7 includes an insulating layer corresponding to the insulating layer 11 illustrated in FIG. 8, and each of the plurality of pads 30P is formed on the insulating layer.

In the present embodiment, the insulating film IF includes an inorganic insulating film CF formed on the main surface 11t and an organic insulating film OF formed on the inorganic insulating film CF. The inorganic insulating film CF is, for example, a silicon oxide film, a silicon nitride film, or a stacked film of these films. On the other hand, the organic insulating film OF is, for example, a resin film such as a polyimide resin film.

As a modification of the present embodiment, there is a case where the organic insulating film OF illustrated in FIG. 8 is not formed and the insulating film IF is composed of only the inorganic insulating film CF.

Since the organic insulating film OF has higher fluidity at a time of formation as compared with the inorganic insulating film CF, the organic insulating film OF is likely to be embedded in unevenness of the surface of the base layer. Therefore, when the organic insulating film OF covering the inorganic insulating film CF is formed, an upper surface of the organic insulating film OF (in other words, the upper surface 10t of the semiconductor chip 10) becomes flat. As illustrated in FIG. 2, in the present embodiment, the semiconductor chip 30 is mounted on the upper surface 10t of the semiconductor chip 10. When another device is mounted on the upper surface 10t of the semiconductor chip 10 as described above, the upper surface 10t of the semiconductor chip 10 is preferably flat.

When the insulating film includes the inorganic insulating film CF and the organic insulating film OF as in the present embodiment, opening portions for exposing the source pad 10P1 from the insulating film IF are formed in each of the inorganic insulating film CF and the organic insulating film OF. Opening portions OPC are formed in the inorganic insulating film CF, and opening portions OPO are formed in the organic insulating film OF.

The opening portions OPC formed in the inorganic insulating film CF are exposed from the organic insulating film OF in the opening portions OPO formed in the organic insulating film. In other words, as illustrated in FIG. 8, the opening portions OPC and the opening portions OPO overlap each other in a thickness direction of the semiconductor chip 10. Therefore, parts of the source pad 10P1 are exposed from the insulating film IF including the inorganic insulating film CF and the organic insulating film OF in the opening portions OPC.

The wires 51 illustrated in FIG. 2 are connected to parts (wire bonding regions) of regions of the source pad 10P1 exposed from the insulating film IF in the wire bonding step illustrated in FIG. 4.

In the present embodiment, the source pad 10P1 is exposed from the insulating film IF at a plurality of locations (two locations in FIGS. 6 and 7). In the case of a structure in which a plurality of parts of one source pad 10P1 are exposed from the insulating film IF as described above, the area of the source pad 10P1 can be increased. A large current flows through the source pad 10P1 during the operation of the power transistor in some cases. Therefore, since the cross-sectional area of the current path can be increased by increasing the area of the source pad 10P1, it is preferable from a viewpoint of reducing resistance of the current path.

Although not illustrated, as a modification of the example illustrated in FIG. 8, there is a case where source pads 10P1 separated from each other are formed at positions where the opening portions OPC and the opening portions OPO are formed.

### <First Semiconductor Chip Mounting Step>

Next, in the first semiconductor chip mounting step illustrated in FIG. 4, the semiconductor chips 10 is mounted on the die pad 20 via the die bond material DB as illustrated in FIG. 2. In the step of mounting the semiconductor chip 10, for example, processing is performed in the following order.

First, the die bond material DB is applied to a chip mounting region (that is, a planned region on which the semiconductor chip 10 is to be mounted) of the die pad 20 (die bond material applying step). When the die bond material DB is made of solder, what is applied in the die bond material applying step is a paste material containing a solder component, a component, and a resin component (referred to as solder paste). On the other hand, when the die bond material DB is a conductive resin, what is applied in the die bond material applying step is a paste material made of a resin mixed with a large number of conductive particles (referred to as a conductive resin paste).

Next, the semiconductor chip 10 is pressed onto the applied paste material to bond the semiconductor chip 10 and the paste material (first semiconductor chip bonding step). In this step, as illustrated in FIG. 2, the side 10s1 of the semiconductor chip 10 among the plurality of sides 10s is arranged along an arrangement direction (X direction in FIG. 2) of the plurality of leads 40.

Next, the die bond material DB is cured to fix the semiconductor chip 10 on the die bond material DB (die bond material curing step). When the paste material applied in the die bond material applying step is a solder paste, a reflow process is performed in this step. The reflow process is a process for heating the die bond material DB until temperature of the die bond material DB becomes equal to or higher than a melting point of the solder component and then cooling the die bond material DB. Through the reflow process, the solder component can be bonded to a metal material to which the die bond material DB is in close contact (in the present embodiment, the die pad 20 and the drain electrode DE of the semiconductor chip). In addition, since the solder component after the reflow process is cured in the state illustrated in FIG. 4, the semiconductor chip 10 is fixed on the die pad 20 via the die bond material DB.

The flux component mentioned above is a surface-activating component used to improve surface activity of the solder component in the reflow process.

On the other hand, when the paste material applied in the die bond material applying step is a conductive resin paste, a cure/bake process is performed in this step. The cure/bake process is a process in which heating is performed until the temperature of the die bond material DB becomes equal to or higher than a curing temperature of the thermosetting resin contained in the conductive resin. The cure/bake process is followed by a cooling step. Since the thermosetting resin component contained in the die bond material DB is cured by performing the cure/bake process, the entire die bond material DB is cured. As a result, the semiconductor chip 10 is fixed on the die pad 20 via the die bond material DB.

### <Second Semiconductor Chip Mounting Step>

Next, in the second semiconductor chip mounting step illustrated in FIG. 4, the semiconductor chip 30 is mounted on the semiconductor chip 10 via the insulating adhesive DT as illustrated in FIG. 3. In the step of mounting the semiconductor chip 30, for example, processing is performed in the following order.

The insulating adhesive DT (see FIG. 3) is attached to the lower surface 30b (see FIG. 3) of the semiconductor chip 30 (see FIG. 3) prepared in the semiconductor chip preparing step illustrated in FIG. 4. The insulating adhesive DT contains an adhesive resin component that can be bonded to each of the semiconductor chip 30 and the semiconductor chip 10 (see FIG. 3) and a thermosetting resin component that can be cured by heating. An adhesive material that can be attached to the semiconductor chip 30 in advance as described above is referred to as a die attach film.

In the second semiconductor chip mounting step, as illustrated in FIG. 3, the insulating adhesive DT attached to the lower surface 30b of the semiconductor chip 30 is attached to the upper surface 10t of the semiconductor chip 10 together with the semiconductor chip 30 (second semiconductor chip attaching step).

In this step, as illustrated in FIG. 2, the side 30s1 (see FIG. 7) of the semiconductor chip 30 among the plurality of sides 30s (see FIG. 7) is arranged along the side 10s1 of the semiconductor chip 10.

Next, the insulating adhesive DT is cured to fix the semiconductor chip 30 on the semiconductor chip 10 (insulating adhesive curing step). In this step, the cure/bake process is performed. The cure/bake process is a process in which heating is performed until temperature of the insulating adhesive DT becomes equal to or higher than the curing temperature of the thermosetting resin contained in the insulating adhesive DT. The cure/bake process is followed by a cooling step. Since the thermosetting resin component contained in the insulating adhesive DT is cured by performing the cure/bake process, the entire insulating adhesive DT is cured. As a result, the semiconductor chip 30 is fixed on the semiconductor chip 10 via the insulating adhesive DT.

The cure/bake process described in the first semiconductor chip mounting step and the cure/bake process described in this step (second semiconductor chip mounting step) may be collectively performed after the second semiconductor chip mounting step. Furthermore, for example, as indicated by a dotted line in FIG. 4, the cure/bake process may be performed as a cure/bake step after the wire bonding step illustrated in FIG. 4 (more specifically, after the quality determining step and before the sealing step). In particular, as illustrated in FIG. 2, the semiconductor chip 30 is mounted near the plurality of pads 10P1 of the semiconductor chip 10. When a gas is generated from the insulating adhesive DT and adheres to a surface of the pad 10P1 during the cure/bake process, electrical characteristics of the joint portions between the wires 51 and the pad 10P1 may be affected. Therefore, from a viewpoint of improving electrical reliability between the wires 51 and the pad 10P1, it is preferable to perform the cure/bake step after the wire bonding step.

### <Wire Bonding Step>

Next, in the wire bonding step illustrated in FIG. 4, the wire 50 is connected to each of the plurality of pads 10P of the semiconductor chip 10 and the plurality of pads 30P of the semiconductor chip 30 as illustrated in FIG. 2. The wire bonding step includes a step of connecting the source pad 10P1 and the leads 40 (the lead 41 and the lead 47) via the wires 51, a step of connecting the pads 10P2 and the pads 30P via the wires 52, and a step of connecting the pads 30P and the leads 40 (the leads 42, 43, 45, and 46) via the wires 53.

As described above, since signal currents flow through the wires 52 and the wires 53, the wires 50 having a wire diameter smaller than that of the wires 51 through which a large current flows are used as the wires 52 and the wires 53. Therefore, in the step of bonding the wires 52 and the wires 53, a ball bonding method using a capillary tool as a bonding tool (bonding head) can be used. On the other hand, as a bonding method for the wires 51, a wedge bonding method using a wedge bonding tool is used.

Details of the wire bonding step, in particular, details of the step of connecting the wires 51 to the source pad 10P1 and the quality determining step performed subsequently thereto will be described later.

### <Quality Determining Step>

Next, in the quality determining step illustrated in FIG. 4, it is determined whether or not ends of the wires 51 illustrated in FIG. 2 are located in the bonding regions in plan view. In this step, a quality determination is performed for the positions of the ends of the wires 51 on the side of the source pad 10P1, which have been connected to the source pad 10P1, among the plurality of wires 50 connected to the semiconductor chip 10 or the semiconductor chip 30 in the wire bonding step. Details of this step will be described later.

### <Sealing Step>

Next, in the sealing step illustrated in FIG. 4, the semiconductor chip 10, a part of the die pad 20, a part of each of the plurality of leads 40 (the inner lead portion 40M illustrated in FIG. 3), and the plurality of wires 50 illustrated in FIG. 2 are sealed by an insulating resin to form the sealing body 60 illustrated in FIG. 3.

In this step, for example, the sealing body 60 is formed by a so-called transfer molding method using a molding die including an upper die (first die) and a lower die (second die) (not illustrated). The lead frame LF is arranged such that the die pads 20 in the device forming portions LFd illustrated in FIG. 5 and the inner lead portion 40M (see FIG. 3) of each of the plurality of leads 40 are located in a cavity of the molding die. The lead frame LF is then sandwiched between the upper die and the lower die. When a softened (plasticized) thermosetting resin (insulating resin) is injected into the cavity of the molding die in this state, the insulating resin is molded into a shape of the cavity.

At this time, a part of the upper surface 20t of the die pad 20 and the lower surface 20b of the die pad 20 are in close contact with the molding die. Therefore, as illustrated in FIG. 3, a part of the upper surface 20t and the lower surface 20b of the die pad 20 are exposed from the sealing body 60 after this step.

After the sealing body 60 is molded, heating is performed until a part of the thermosetting resin contained in sealing body 60 is cured (referred to as provisional curing). When it becomes possible to take out the lead frame LF from the molding die as a result of the provisional curing, the lead frame LF is taken out of the molding die. Then, the lead frame LF is conveyed to a heating furnace and further subjected to heat treatment (cure/bake). As a result, the remainder of the thermosetting resin is cured to obtain the sealing body 60.

### <Solder Film Forming Step>

Next, in the solder film forming step illustrated in FIG. 4, the lead frame LF is immersed in a plating solution (not illustrated), and the metal films (the metal film 22 and the metal film 48 illustrated in FIG. 3) are formed on surfaces of metal portions (outer portions) exposed from the sealing body 60.

### <Dicing Step>

Next, the dicing step illustrated in FIG. 4 includes a tie bar cutting step of cutting the tie bars LFt1 illustrated in FIG. 5 and a lead cutting step of cutting a tip portion of each of the plurality of leads 40 illustrated in FIG. 5.

In the tie bar cutting step, the tie bars LFt1 illustrated in FIG. 5 are cut. In the tie bar cutting step, the tie bars LFt2 are also cut, and the plurality of die pads 20 connected via the tie bars LFt2 is divided. After this step, the plurality of leads 40 is connected via the frame portions LFf.

As a method of cutting the tie bars LFt1 and LFt2, press working (cutting) using a punch and a die (not illustrated) can be used. Since this step is performed after the solder film forming step, side surfaces newly formed through the cutting in this step are not covered with the metal film 48.

In the lead cutting step, the plurality of leads 40 is separated from each other by separating the plurality of leads 40 from the frame portions LFf. In this step, the tip portion of each of the plurality of leads 40 is cut through press working (cutting) using a punch and a die (not illustrated). Tip surfaces newly formed through the cutting in this step are not covered with the metal film 48. Through this step, the device forming portions LFd illustrated in FIG. 5 are divided into pieces, and the semiconductor device illustrated in FIG. 1 is obtained.

Through the above steps, the semiconductor device PKG1 illustrated in FIGS. 1 to 4 is obtained. Thereafter, after a test or an inspection such as an electrical test or an appearance inspection is performed as necessary, products determined to be non-defective products are conveyed to a next step such as a step of packaging a semiconductor device.

### <Details of Wire Bonding Step>

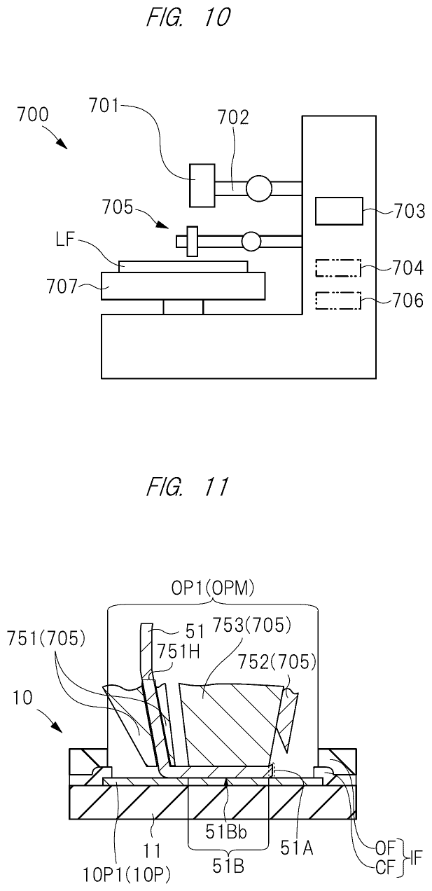

Next, details of the wire bonding step and the quality determining step will be described. Hereinafter, a step of connecting the wires 51 illustrated in FIG. 2 to the source pad 10P1 will be described in detail. FIG. 9 is an explanatory view illustrating an example of detailed steps of the wire bonding step illustrated in FIG. 4. FIG. 10 is an explanatory view schematically illustrating a configuration example of a wire bonding device used in the wire bonding step illustrated in FIG. 4.

As illustrated in FIG. 9, the wire bonding step according to the present embodiment includes a semiconductor chip distinguishing step, an identifying step of the position of an opening portion, an identifying step of a bonding region, and a wire forming step.

In the example illustrated in FIG. 10, a wire bonding device 700 includes a camera (an image sensor or an imaging processing unit) 701, a camera conveyance unit 702, a monitor 703, a semiconductor chip distinguishing unit 704, a bonding processing unit 705, and a determination unit 706. Note that the wire bonding device 700 illustrated in FIG. 10 is an example, and various modifications can be applied. For example, in the case of the wire bonding device 700 illustrated in FIG. 10, the camera 701 and the bonding processing unit 705 are configured to operate independently. As a modification of FIG. 10, there is a case where the camera 701 and the bonding processing unit 705 are driven by the same drive unit. Further, for example, the monitor 703 is attached to the wire bonding device 700 in FIG. 10. A position of the monitor 703 is not limited to the example illustrated in FIG. 10, and may be arranged at, for example, a position away from the wire bonding device 700.

The camera 701 is configured to be able to capture an image of the semiconductor chips mounted on the lead frame LF conveyed onto a stage 707. The camera 701 is configured to be movable using the camera conveyance unit 702. The image captured by the camera 701 is displayed on the monitor 703. The monitor 703 can display the image captured by the camera 701. In addition to the image captured by the camera 701, lines that serve as a guide for an operator to visually check the positional relationship between the opening portions and the wires may be displayed on the monitor 703.

In the wire bonding step illustrated in FIG. 9, first, the camera 701 (see FIG. 10) provided in the wire bonding device 700 (see FIG. 10) recognizes a unique pattern on the semiconductor chip 10 (see FIG. 6) to distinguish the semiconductor chip (semiconductor chip distinguishing step).

The semiconductor chip distinguishing unit 704 of the wire bonding device 700 illustrated in FIG. 10 is configured to distinguish a semiconductor chip based on an image captured by the camera 701 and displayed on the monitor 703. For example, the semiconductor chip distinguishing unit 704 is configured to distinguish a semiconductor chip by identifying a unique pattern from an image displayed on the monitor 703.

Examples of the unique pattern include a method in which one or more of the plurality of pads 10P of the semiconductor chip 10 illustrated in FIG. 6 is used and a method in which a visible mark dedicated for distinguishing is formed in advance on the upper surface 10t of the semiconductor chip 10. In the present embodiment, the opening portions for the source pad 10P1 can be used as the unique pattern.

Next, positions of the opening portions where parts of the source pad 10P1 of the semiconductor chip 10 are exposed among the plurality of opening portions formed in the insulating film IF illustrated in FIG. 6 are identified based on coordinate data regarding the opening portions obtained in advance with the unique pattern defined as an origin (identifying step of the position of an opening portion).

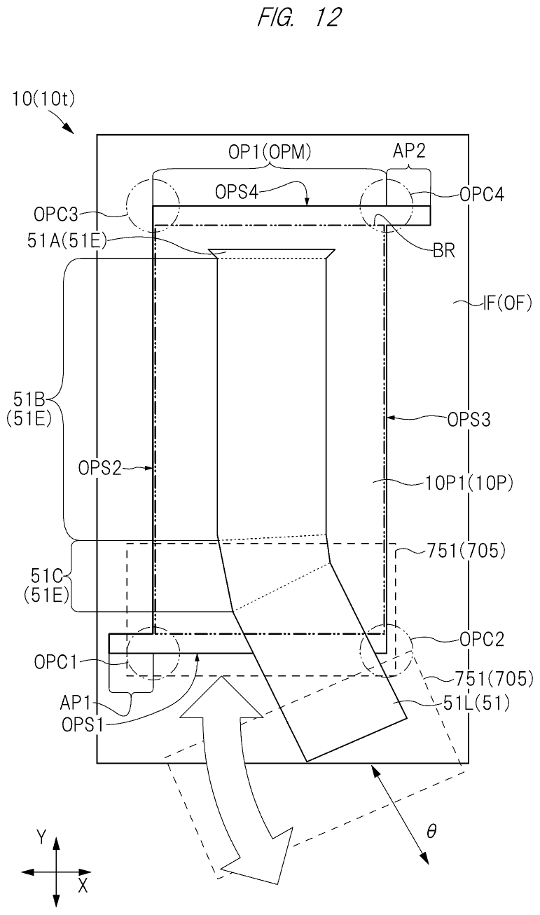

Next, the region for connecting the wire 51 (see FIG. 2) in the opening portion formed in the insulating film IF (a bonding region BR illustrated in FIG. 12, which will be described later) is identified (identifying step of a bonding region). This step is performed after the semiconductor chip preparing step illustrated in FIG. 4 and before the wire forming step illustrated in FIG. 9.

The source pad opening portions formed in the insulating film IF of FIG. 6 are formed to expose, from the insulating film IF, the bonding regions of the source pad 10P1 for connecting the wires 51. However, considering versatility of the semiconductor chip 10, opening ranges of the opening portions do not necessarily match the bonding regions, and the source pad 10P1 may be exposed in ranges wider than the bonding regions to which the wires 51 are connected.

From a viewpoint of suppressing characteristic fluctuation of the semiconductor device, it is preferable that the wires 51 are connected in the bonding regions in the source pad 10P1 set by design in advance. Therefore, the wire bonding step preferably includes the identifying step of a bonding region.

The identifying step of a bonding region is referred to as “teaching”. The “teaching” is performed to improve accuracy of the positions where the wires 51 are connected from the viewpoint of suppressing the characteristic fluctuation of the semiconductor device due to misalignment of bonding positions where the bonding wires are connected. Details of the “teaching” will be described later.

As described with reference to FIG. 4, the present embodiment includes the quality determining step performed after the wire bonding step. Therefore, if a result of the quality determination can be fed back to fine adjustment of settings of the wire bonding device 700 (see FIG. 10), the identifying step of a bonding region may be omitted.

Next, the wires 51 (see FIG. 2) are connected to the source pad 10P1 illustrated in FIG. 6 (wire forming step). When the identifying step of a bonding region is performed before this step, the ends of the wires 51 (see FIG. 2) are connected in the wire forming step to the bonding regions of the source pad 10P1 based on information identified in the “teaching”. Hereinafter, details of the wire forming step illustrated in FIG. 9 will be described with reference to FIGS. 3, 11, and 12. FIG. 11 is an enlarged cross-sectional view illustrating a first bonding step of the wire forming step. FIG. 12 is a plan view schematically illustrating operation of a wedge tool in a bent portion forming step of the wire forming step.

The bonding processing unit 705 of the wire bonding device 700 illustrated in FIG. 10 includes a wire guide 751, a cutting blade 752, and a wedge tool 753 illustrated in FIG. 11.

In the wire forming step illustrated in FIG. 9, first, as illustrated in FIG. 11, the end of the wire 51 is brought into contact with a portion of the source pad 10P1 exposed from the insulating film IF in the opening portion OP1, and the wire 51 is sandwiched between the wedge tool 753 and the source pad 10P1. At this time, the wedge tool 753 applies ultrasonic waves while pressing the wire 51 in a direction of the source pad 10P1 (first bonding step).

Through the first bonding step, a bonding portion 51B of the end of the wire 51 is bonded to the source pad 10P1. Note that the bonding portion 51B is a portion of the wire 51 including a bonding surface 51Bb, which is a bonding interface with the source pad 10P1, and a portion overlapping the bonding surface 51Bb in a thickness direction of the wire 51.

On the other hand, as illustrated in FIG. 11, a tip portion 51A of the end of the wire 51 located closer to a tip than the bonding portion 51B is may not contact the wedge tool 753 in the first bonding step. In this case, the tip portion 51A that is not bonded to the source pad 10P1 is formed at the tip of the wire 51.

Next, the wire guide 751 illustrated in FIG. 11 is pulled upward while unwinding the wire 51 from a wire supply hole 751H formed in the wire guide 751. Thereafter, as schematically illustrated in FIG. 12 with an arrow, when the wire guide 751 (see FIG. 11) is rotated along the X-Y plane, a bent portion (part) 51C is formed (bent portion forming step).

In this specification, the tip portion 51A, the bonding portion 51B, and the bent portion 51C illustrated in FIG. 12 will be described as an end portion 51E of the wire 51.

In FIG. 12, dotted lines are given to a boundary between the bent portion 51C and the bonding portion 51B and a boundary between the bent portion 51C and an extending portion 51L in order to clearly specify these boundaries. Also, the bent portion 51C extends in a direction different from any of the X direction, the Y direction, and a θ direction. However, it is sometimes difficult to specify the boundary between the bent portion 51C and the extending portion 51L formed in the bent portion forming step. For example, when the bent portion 51C extends in the θ direction as with the extending portion 51L, it is difficult to identify the boundary between the bent portion 51C and the extending portion 51L.

Next, while unwinding the wire 51 from the wire supply hole 751H formed in the guide 751 illustrated in FIG. 11, the wire guide 751 is moved toward the lead 47 illustrated in FIG. 3 and bonded to the wire bonding portion 40W of the lead 47 (second bonding step). In the second bonding step, as with the first bonding step, the wire 51 is pressed to the upper surface 40t of the lead 47 with the wedge tool 753 (see FIG. 11) and bonded by applying ultrasonic waves.

Next, the wire 51 is cut with the cutting blade 752 illustrated in FIG. 11 (wire cutting step).

Through the above steps, the wire 51 illustrated in FIG. 2 is obtained. As illustrated in FIG. 12, the wire 51 includes the end portion 51E including the bonding portion 51B having a bonding surface, which is a bonding interface with the pad 10P1, and the extending portion 51L connected to the end portion 51E and extending in the θ direction intersecting each of the X direction and the Y direction in plan view. In plan view, the extending portion 51L intersects the side OPS1. As described above, the end portion 51E of the wire 51 includes the tip portion 51A, the bonding portion 51B, and the bent portion 51C.

### <Teaching>

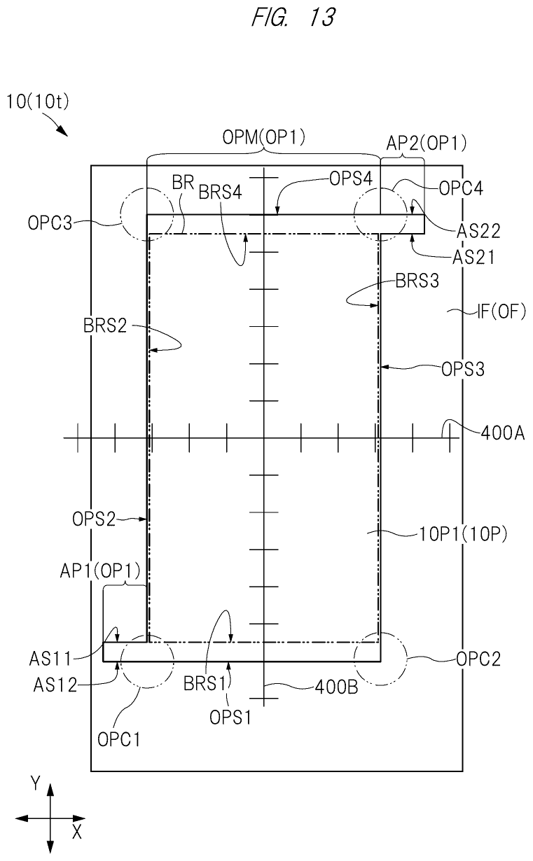

Next, details of the “teaching” performed in the identifying step of a bonding region of FIG. 9 will be described. FIG. 13 is an explanatory diagram illustrating an example of an image displayed on a monitor at a time of “teaching” performed in the identifying step of a bonding region of FIG. 9. In FIG. 13, an outer edge of the bonding region BR and outer edges of corner portions OPC1, OPC2, OPC3, and OPC4 are indicated by dash-dot-dot lines, but in the “teaching”, lines of the bonding region BR and the corner portions OPC1, OPC2, OPC3, and OPC4 are not displayed on the monitor 703 (see FIG. 10).

In FIG. 13, first, a positional relationship between the lead frame LF (see FIG. 10) on which the semiconductor chip 10 is mounted and the camera 701 is adjusted such that the opening portion OP1 (more specifically, the main opening portion OPM) including the bonding region BR is arranged immediately below the camera 701 (see FIG. 10). As a result, as illustrated in FIG. 13, an image of the opening portion OP1 captured by the camera 701 is displayed on the monitor 703 (see FIG. 10) of the wire bonding device 700 (see FIG. 10). For example, the opening portion OP1 illustrated in FIG. 13 has the main opening portion OPM including the bonding region BR.

Note that the bonding region BR is a planned region where the end portion 51E of the wire 51 illustrated in FIG. 12 is to be arranged. In the present embodiment, when at least a whole of the bonding portion 51B of the wire 51 illustrated in FIG. 12 is located within a range of the bonding region BR in plan view in the quality determining step illustrated in FIG. 4, it is determined as a non-defective product. Preferably, when a whole of the end portion 51E, which includes the bonding portion 51B and the bent portion 51C, of the wire 51 is located within the range of the bonding region BR, it is determined as a non-defective product.

In plan view, the main opening portion OPM includes the side OPS1 extending in the X direction, the side OPS2 extending in the Y direction intersecting the X direction, the side OPS3 extending in the Y direction and located on a side opposite the side OPS2, and the side OPS4 extending in the X direction and located on the side opposite the side OPS1.

As illustrated in FIG. 12, in the wire bonding step, the wire 51 (more specifically, the extending portion 51L of the wire 51) is formed so as to straddle the side OPS1 of the main opening portion OPM in plan view.

Further, the main opening portion OPM includes the corner portion OPC1 including an intersection between the side OPS1 and an extended line of the side OPS2, the corner portion OPC2 including an intersection between the side OPS1 and the side OPS3, the corner portion OPC3 including an intersection between the side OPS4 and the side OPS2, and the corner portion OPC4 including an intersection between the side OPS4 and an extended line of the side OPS3.

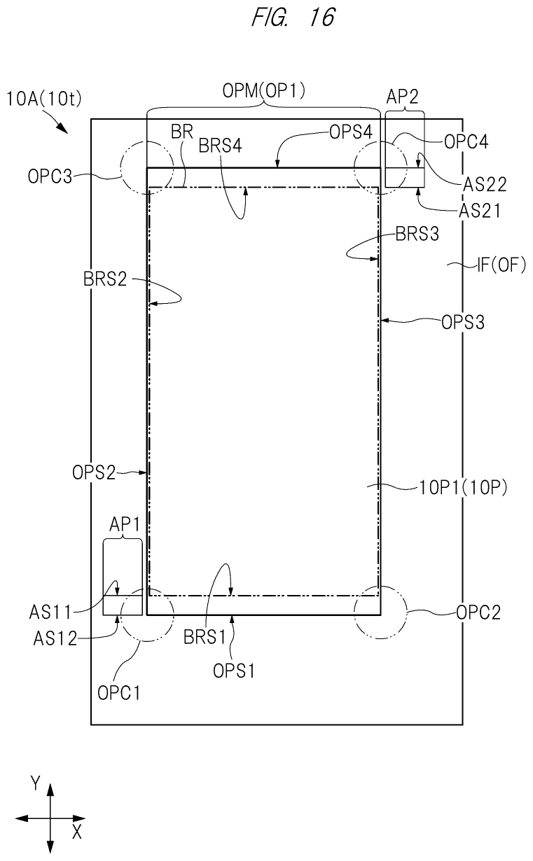

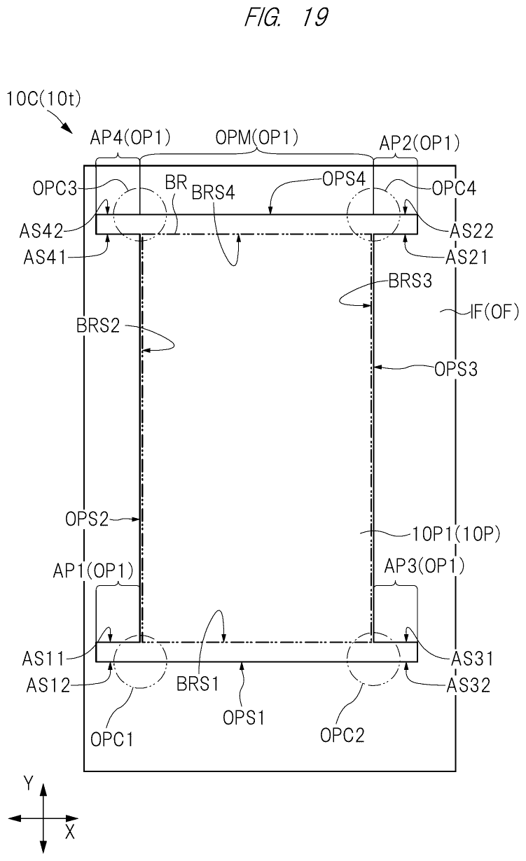

In the case of the example illustrated in FIG. 12, definitions of the corner portions OPC1 to OPC4 are as described above, but the definitions of the corner portions are modified as appropriate in accordance with a positional relationship between the main opening portion OPM and a position determining opening pattern. For example, in a modification illustrated in FIG. 16, which will be described later, the main opening portion OPM includes the corner portion OPC1 including an intersection between the side OPS1 and the side OPS2, the corner portion OPC2 including an intersection between the side OPS1 and the side OPS3, the corner portion OPC3 including an intersection between the side OPS4 and the side OPS2, and the corner portion OPC4 including an intersection between the side OPS4 and the side OPS3. Further, for example, in a modification illustrated in FIG. 19, which will be described later, the main opening portion OPM includes the corner portion OPC1 including an intersection between the side OPS1 and the side OPS2, the corner portion OPC2 including an intersection between the side OPS1 and an extended line of the side OPS3, the corner portion OPC3 including an intersection between the side OPS4 and an extension of the side OPS2, and the corner portion OPC4 including an intersection between the side OPS4 and the side OPS3.

Furthermore, although not illustrated, there is a case where a position determining opening pattern AP1 is arranged at the corner portion OPC2 instead of at the corner portion OPC1 as a modification of FIG. 12. In this case, the corner portion OPC2 includes an intersection between the side OPS1 and an extended line of the side OPS3. In addition, when a position determining opening pattern AP2 illustrated in FIG. 12 is arranged at the corner portion OPC3, the corner portion OPC3 includes an intersection between the side OPS4 and an extended line of the side OPS2.

A planar shape of the main opening portion OPM is a rectangle having long sides and short sides, and the length of the long sides (the side OPS2 and the side OPS3) is about 1200 μm. On the other hand, the length of the short sides (the side OPS1 and the side OPS4) is about 600 μm.

Next, while viewing an image displayed on the monitor 703 (see FIG. 10), the operator moves the camera 701 (see FIG. 10) such that the bonding region BR is located at the center of the image, visually adjusts the position, and identifies the bonding region BR.

As illustrated in FIG. 13, for example, a cross line made up of a horizontal line 400A and a vertical line 400B is displayed on the monitor 703 (see FIG. 10), and the bonding region BR is identified based on the cross line. Scale marks are given at regular intervals on each of the horizontal line 400A and the vertical line 400B, and a center position of the cross line is adjusted by moving the center of the cross line to the vicinity of the center of the main opening portion OPM such that the number of scale marks from the center of the cross line to each of the upper, lower, left, and right sides of the main opening portion OPM becomes the same. For example, the interval of the scale marks given on each of the horizontal line 400A and the vertical line 400B constituting the cross line is, for example, about 100 μm.

However, when only the above-described “teaching” is performed, there is a limit to accuracy of identifying the bonding region BR or positional accuracy of the bonding portion 51B of the actually connected wire 51.

For example, dimensions (width and length) of the main opening portion OPM of the source pad 10P1 to which the wire 51 is connected vary depending on a type of semiconductor device. Therefore, the dimensions of the main opening portion OPM may not be an integral multiple of the interval of the scale marks given to each of the horizontal line 400A and the vertical line 400B constituting the cross line of the wire bonding device 700 (see FIG. 10) used. In such a case, the operator visually checks “1 scale mark×integer+α scale mark (α is a decimal)”, and aligns the intersection of the cross line with the center of the main opening portion OPM. At this time, it is difficult for the operator to accurately adjust the center position of the cross line visually so as to have the same “1 scale mark×integer+α scale mark” from the center of the cross line to each of the upper, lower, left, and right sides of the main opening portion OPM. Therefore, with only the above-described “teaching”, a misalignment of, for example, about 10% of one scale mark (about several tens of micrometers) occurs when identifying the bonding region BR.

Also, for example, since the “teaching” is an aligning step performed before the wire 51 (see FIG. 12) is connected to the source pad 10P1, a position of the wire 51 after actual bonding may be misaligned from a planned position depending on settings and characteristics of the wire bonding device 700 (see FIG. 10).

Accordingly, although the position of the bonding region BR can be identified by the “teaching”, there is a limit to the positional accuracy of the bonding portion 51B of the actually connected wire 51 only with the “teaching” as described above.

Incidentally, considering only the presence of electrical conduction, it is sufficient if at least a part of the wire 51 illustrated in FIG. 12 is connected to the source pad 10P1. In this case, if the bonding portion 51B of the wire 51 is arranged in the main opening portion OPM, the electrical conduction can be obtained even if another portion (for example, the tip portion 51A and the bent portion 51C) of the wire 51 is located outside the main opening portion OPM in plan view.

On the other hand, considering the characteristics of the semiconductor device, the characteristics may fluctuate depending on a position of the source pad 10P1 where the bonding portion 51B of the wire 51 is arranged.

For example, in the case of the semiconductor device PKG1 having the sense transistor TrS as illustrated in FIG. 2, a separation distance L1 between the sense transistor TrS and the bonding portion 51B (see FIG. 12) of the wire 51 correlates with a detected value. As described above, the sense transistor TrS has a function of detecting a current value of the current flowing through the main transistor TrM. The detected current value correlates with the separation distance L1.

Therefore, even when the bonding portion 51B is arranged in the main opening portion OPM, a different current value is detected depending on the position of the bonding portion 51B in the main opening portion OPM. For this reason, in order to improve accuracy of the current value detected by the sense transistor TrS, it is preferable to improve the positional accuracy of the bonding portion 51B in the main opening portion OPM. In other words, the accuracy of the current value detected by the sense transistor Trs can be improved by improving the positional accuracy of the bonding portion 51B in the main opening portion OPM.

In the example illustrated in FIG. 6, when an extended line obtained by extending the side OPS2 in the Y direction is defined an extended line VL1 and an extended line obtained by extending the side OPS3 in the Y direction is defined an extended line VL2 in plan view, the sense transistor TrS is located between the extended line VL1 and the extended line VL2 in transparent plan view. Therefore, in order to set a value of the separation distance L1 illustrated in FIG. 6 within an allowable range, positions of a side BRS4 and a side BRS1 are particularly important among the side BRS1, a side BRS2, a side BRS3, and the side BRS4 of the bonding region BR illustrated in FIG. 13.

In addition, as described above, considering the versatility of the semiconductor chip 10, an opening range of the main opening portion OPM does not necessarily match the bonding region BR, and the source pad 10P1 may be exposed in a wider range than the bonding region BR to which the wire 51 is connected. For this reason, in order to improve the positional accuracy of the bonding portion 51B in the main opening portion OPM, a technique of accurately arranging the bonding portion 51B in the bonding region BR having a small opening area of the main opening portion OPM is required.

Based on the above knowledge, the inventors of this application have studied a technique for improving positional accuracy of the bonding portion 51B in the actually connected wire 51, and has found the method of manufacturing a semiconductor device according to the present embodiment.

### <Details of Quality Determining Step>

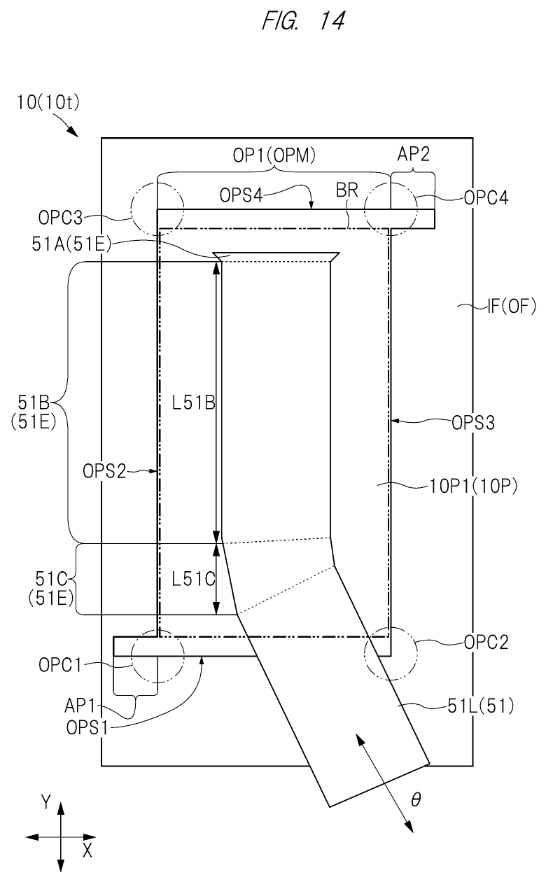

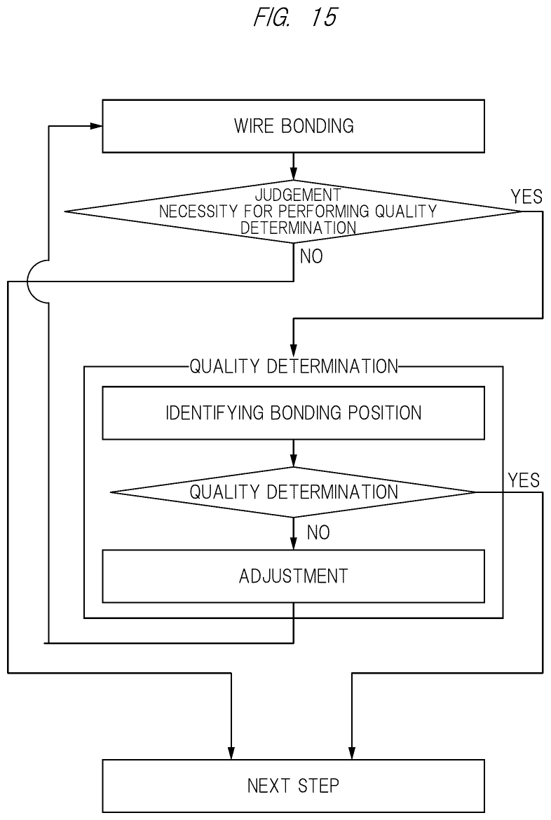

FIG. 14 is an explanatory diagram illustrating an example of an image displayed on the monitor in the quality determining step illustrated in FIG. 4. In FIG. 14, the outer edge of the bonding region BR and the outer edges of the corner portions OPC1, OPC2, OPC3, and OPC4 are indicated by dash-dot-dot lines, but the line of the bonding region BR is not displayed on the monitor 703 (see FIG. 10) in the quality determining step. Also, in FIG. 14, dotted lines are given to a boundary between the tip portion 51A and the bonding portion 51B, the boundary between the bonding portion 51B and the bent portion 51C, and the boundary between the bent portion 51C and the extending portion 51L. However, the lines of the boundaries indicated in FIG. 14 by the dotted lines are not displayed in the quality determining step. FIG. 15 is an explanatory diagram illustrating details of the quality determining step illustrated in FIG. 4.

As illustrated in FIG. 15, the quality determining step includes an identifying step of the position of a bonding, a quality determining step, and an adjustment step. First, in the identifying step of the position of a bonding, a positional relationship between the bonding portion 51B (see FIG. 14) or the end portion 51E (see FIG. 14) of the wire 51 (see FIG. 14) and the bonding region BR (see FIG. 14) is identified based on the image displayed on the monitor 703 (see FIG. 10) of the wire bonding device 700 (see FIG. 10).

In FIG. 14, the semiconductor chip 10 includes a plurality of position determining opening patterns arranged in a region located around the main opening portion OPM in plan view. In each of the sides OPS1 and OPS4 of the main opening portion OPM, when an extended line extending in a direction from the side OPS3 toward the side OPS2 in plan view is defined an extended line HL1 (see FIG. 6) and an extended line extending in a direction from the side OPS2 toward the side OPS3 is defined as an extended line HL2 (see FIG. 6), positions of the plurality of position determining opening patterns can be defined as follows. That is, the plurality of position determining opening patterns includes the position determining opening pattern AP1 located between the extended line HL1 (see FIG. 6) of the side OPS1 and the extended line HL1 of the side OPS4 in the Y direction and arranged at a position closest to the corner portion OPC1 among the corner portion OPC1, the corner portion OPC2, the corner portion OPC3, and the corner portion OPC4 of the main opening portion OPM. Also, the plurality of position determining opening patterns further includes the position determining opening pattern AP2 located between the extended line HL2 (see FIG. 6) of the side OPS1 and the extended line HL2 of the side OPS4 in the Y direction and arranged at a position closest to the corner portion OPC3 or the corner portion OPC4 among the corner portion OPC1, the corner portion OPC2, the corner portion OPC3, and the corner portion OPC4 of the main opening portion OPM.

The bonding region BR has a rectangular shape having an area smaller than the opening area of the main opening portion OPM in plan view. The bonding region BR is defined by the position determining opening pattern AP1, the position determining opening pattern AP2, the side OPS2, and the side OPS3.

As illustrated in FIG. 14, the images of the opening portion OP1 including the main opening portion OPM and the wire 51 are displayed on the monitor 703 (see FIG. 10). When image processing or the like for displaying the bonding region BR is not particularly performed, a line indicating the outer edge of the bonding region BR is not displayed on the monitor 703. However, in the present embodiment, the position determining opening pattern AP1 and the position determining opening pattern AP2 for defining the range of the bonding region BR are provided for the corner portion OPC1 and the corner portion OPC4, respectively. Therefore, when the position determining opening pattern AP1 and the position determining opening pattern AP2 are used as references, the boundary of the bonding region BR can be easily identified visually.

Next, in the quality determining step, the quality is determined based on whether or not at least a whole of the bonding portion 51B is located in the bonding region BR. Preferably, the quality is determined based on whether or not a whole of the end portion 51E including the bonding portion 51B and the bent portion 51C is located in the bonding region BR. For example, when a part of the end portion 51E (for example, a part of the bent portion 51C or a part of the tip portion 51A) is located outside the bonding region BR, NO (that is, defective) is determined, and the process proceeds to the adjustment step described later. On the other hand, when a whole of the end portion 51E is located in the bonding region BR, YES (that is, acceptable) is determined, and the process proceeds to the next step (for example, bonding of another wire or the sealing step illustrated in FIG. 4).

As a modification of the present embodiment, the quality may be determined based on whether or not a whole of the bonding portion 51B is located in the bonding region BR in the quality determining step. In this case, when at least a whole of the bonding portion 51B is arranged in the bonding region BR, YES (that is, acceptable) is determined even if a part of the end portion 51E (for example, a part of the bent portion 51C or a part of the tip portion 51A) is located outside the bonding region BR, and the process proceeds to the next step (for example, bonding of another wire or the sealing step illustrated in FIG. 4). On the other hand, when a part of the bonding portion 51B is arranged outside the bonding region BR, NO (that is, defective) is determined, and the process proceeds to the adjustment step described later.

However, from a viewpoint of further improving the accuracy of the current value detected by the sense transistor TrS, it is preferable to perform the quality determination based on whether or not a whole of the end portion 51E of the wire 51 including not only the bonding portion 51B but also the tip portion 51A and the bent portion 51C is located in the bonding region BR as in the present embodiment.

As described above, in FIG. 14, dotted lines are given to the boundary between the tip portion 51A and the bonding portion 51B, the boundary between the bonding portion 51B and the bent portion 51C, and the boundary between the bent portion 51C and the extending portion 51L. However, the lines of the boundaries indicated in FIG. 14 by the dotted lines are not displayed on the monitor 703 (see FIG. 10) in the quality determining step. Therefore, when the shape of the wire 51 is as illustrated in FIG. 14, it is difficult to specify the boundary between the tip portion 51A and the bonding portion 51B and the boundary between the bonding portion 51B and the bent portion 51C in the end portion 51E of the wire 51 in plan view based on the displayed image. On the other hand, the boundary between the bent portion 51C and the extending portion 51L can be easily specified from a planar image. For example, even when the operator visually checks the image on the monitor 703, it is possible to specify the boundary between the bent portion 51C and the extending portion 51L.

As described in the bent portion forming step of the wire bonding step, it is sometimes difficult to specify the boundary between the bent portion 51C and the extending portion 51L formed in the bent portion forming step. In this case, a positional range of the bent portion 51C is preferably set as follows.

That is, as illustrated in FIG. 14, the length of the bent portion 51C in the Y direction is a length L51C. Then, the length L51C is 8% or more and 12% or less of a length L51B of the bonding portion 51B in the Y direction. More specifically, the length L51C is a value set in advance within a range of 8% or more and 12% or less of the length L51B.

When the bent portion 51C extends in the θ direction as with the extending portion 51L, the bent portion 51C seems to be integrated with the extending portion 51L. Therefore, it is difficult to specify the boundary between the bent portion 51C and the extending portion 51L. On the other hand, when the bent portion 51C extends in a direction different from the θ direction, the boundary between the bent portion 51C and the extending portion 51L can be easily specified.

Therefore, when it is difficult to specify the boundary between the bent portion 51C and the extending portion 51L, the length L51C proportional to the length L51B of the bonding portion 51B in the Y direction is set, and a part of the wire 51 within the range of the length L51C is regarded as the bent portion 51C. In this way, even if the boundary between the bent portion 51C and the extending portion 51L is unclear, the quality determination can be performed based on the same criteria as in the case where the boundary between the bent portion 51C and the extending portion 51 L can be easily specified.

In addition, if a product is determined to be defective in the quality determining step, the wire bonding device 700 illustrated in FIG. 10 is adjusted.

According to the study conducted by the inventors of this application, deviation of a part of the bonding portion 51B or a part of the end portion 51E of the wire 51 from the range of the bonding region BR after the wire bonding step tends to be detected in one of the following three cases.

First, after the wire bonding device 700 (see FIG. 10) for performing the wire bonding step is activated and a first wire is bonded, misalignment of the end portion 51E may be detected. Second, after a jig (for example, the wedge tool 753 illustrated in FIG. 11) attached to the wire bonding device 700 (see FIG. 10) is replaced in the wire bonding step, misalignment of the end portion 51E may be detected. Third, after wire bonding conditions for performing wire bonding in the wire bonding step is changed, misalignment of the bonding portion 51B (or the end portion 51E) may be detected.

On the other hand, in the case other than the above-described three cases, misalignment of the bonding portion 51B (or the end portion 51E) is unlikely to be detected. In other words, a cause of misalignment of the bonding portion 51B (or the end portion 51E) mainly results from a setting condition of the wire bonding device 700 (see FIG. 10) and an attachment condition of a jig.

Therefore, in the adjustment step of the wire bonding device 700 (see FIG. 10), one or more of the following items are adjusted. First, the adjustment of the wire bonding device 700 includes adjustment of setting of the wire bonding conditions. The setting of the wire bonding conditions includes, for example, adjustment of pressing force when a wire is bonded, adjustment of setting of an ultrasonic output, adjustment of setting of operation timing of the bonding processing unit 705 (see FIG. 10), and the like. The adjustment of the wire bonding device 700 further includes checking and adjustment of an attached state of the jig (for example, the wedge tool 753 illustrated in FIG. 11) attached to the wire bonding device 700 (see FIG. 10).

After the adjusting step, the quality determining step is performed again after another wire is bonded. By repeatedly performing the adjustment step and the quality determining step in this manner, it is possible to achieve a setting with which an “acceptable” result is obtained in the quality determination.

A step of determining necessity to perform the quality determination illustrated in FIG. 15 may be omitted. In this case, every time the wire bonding step is completed, the quality determining step is performed. However, from a viewpoint of improving manufacture efficiency, a mode illustrated in FIG. 15 is more preferable.

In the example illustrated in FIG. 15, the step of determining whether to perform the quality determination (the step of determining necessity to perform the quality determination) is included after the wire bonding step and before the quality determining step. In the step of determining necessity to perform the quality determination, the determination is performed based on whether or not the wire bonding step performed immediately before corresponds to the timing of any of the above-mentioned three cases. When the wire bonding step corresponds to the timing of any of the above-mentioned three cases, YES (that is, the quality determining step is necessary) is determined, and the process proceeds to the quality determining step. On the other hand, when the wire bonding step does not correspond to the timing of any of the above-mentioned three cases, NO (that is, the quality determining step is unnecessary) is determined, the quality determining step is omitted, and the process proceeds to the next step (for example, bonding of another wire or the sealing step illustrated in FIG. 4).

In other words, in the example illustrated in FIG. 15, the quality determining step is selectively performed after the wire bonding device 700 (see FIG. 10) for performing the wire bonding step is activated and the first wire is bonded, after the jig (for example, the wedge tool 753 illustrated in FIG. 11) attached to the wire bonding device 700 (see FIG. 10) is replaced in the wire bonding step, or after the wire bonding conditions for performing the wire bonding in the wire bonding step are changed.

If the quality determining step is performed at the timing corresponding to at least one of the above-mentioned three cases, there is a low possibility that a large number of defective products are manufactured even if the quality determining step is omitted at the other timings. Further, even if defective products are manufactured, the defective products can be eliminated by performing an electrical test after the dicing step illustrated in FIG. 4 is completed.

The quality determining step is regarded as an inspection step for promptly correcting misalignment caused by the setting of the wire bonding device 700 (see FIG. 10) and the attachment condition of the jig.

### <Shape of Opening Portion>

Next, detailed structures of the main opening portion OPM, the position determining opening pattern AP1, and the position determining opening pattern AP2 illustrated in FIG. 14 and a positional relationship with the bonding region BR will be described with the inclusion of modifications.

As illustrated in FIG. 13, in plan view, the position determining opening pattern AP1 includes an inner side AS11 extending in the X direction and an outer side AS12 extending in the X direction and arranged at a position closer to the side OPS1 than the inner side AS11 is. In plan view, the position determining opening pattern AP2 includes an inner side AS21 extending in the X direction and an outer side AS22 extending in the X direction and arranged at a position closer to the side OPS4 than the inner side AS21 is.

In the identifying step of the position of a bonding illustrated in FIG. 15, the bonding region BR is defined by an extended line of the inner side AS11 of the position determining opening pattern AP1, an extended line of the inner side AS21 of the position determining opening pattern AP2, the side OPS2, and the side OPS3.

The structure illustrated in FIG. 13 can be expressed as follows. The bonding region BR includes the side BRS1 extending in the X direction, the side BRS2 extending in the Y direction and intersecting the side BRS1, the side BRS3 extending in the Y direction, intersecting the side BRS1, and located on a side opposite the side BRS2, and the side BRS4 extending in the X direction, intersecting the side BRS2 and the side BRS3, and located on a side opposite the side BRS1. An extended line of the side BRS1 overlaps the inner side AS11 of the position determining opening pattern AP1. Further, an extended line of the side BRS4 overlaps the inner side AS21 of the position determining opening pattern AP2.

From the viewpoint of accurately identifying the position of the bonding region BR, it is more preferable to identify the position of the bonding region BR based on the positions of the inner side AS11 and the inner side AS21 rather than identifying the position of the bonding region BR based on any positions of the position determining opening pattern AP1 and the position determining opening pattern AP2.

In the present embodiment, since the position of the bonding region BR can be accurately identified based on the positions of the inner side AS11 and the inner side AS21, the cross line (the horizontal line 400A and the vertical line 400B) illustrated in FIG. 13 may not be displayed on the monitor 703 (see FIG. 10) in the identifying step of a bonding region illustrated in FIG. 9.

Also, as illustrated in FIG. 13, the opening area of each of the position determining opening pattern AP1 and the position determining opening pattern AP2 is smaller than the opening area of the main opening portion OPM. This structure is preferable from the viewpoint of improving the accuracy of identifying the outer edge of the bonding region BR.

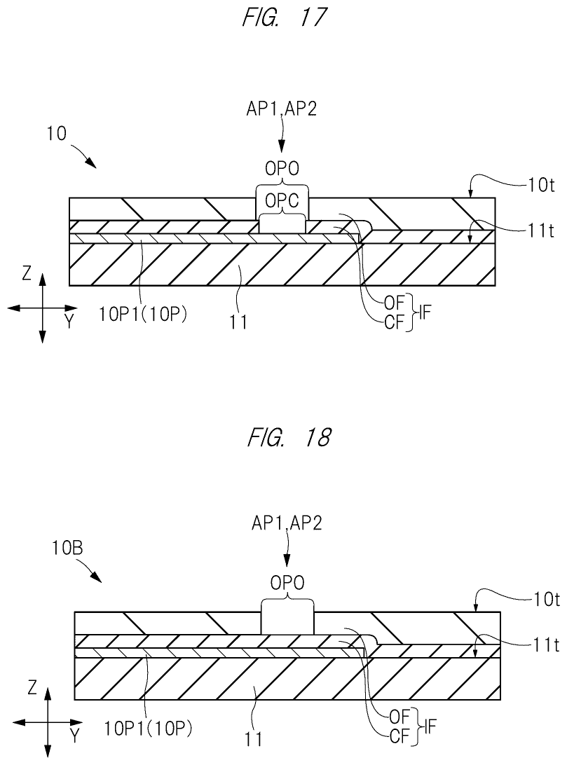

As described with reference to FIG. 8, the insulating film IF may include the inorganic insulating film CF formed on the main surface 11t and the organic insulating film OF formed on the inorganic insulating film CF. The main opening portion OPM illustrated in FIG. 13 is formed in both the inorganic insulating film CF and the organic insulating film OF illustrated in FIG. 8. Furthermore, for example, as illustrated in FIG. 17, which will be described later, each of the position determining opening pattern AP1 and the position determining opening pattern AP2 is formed in both the inorganic insulating film CF and the organic insulating film OF. Alternatively, as illustrated in FIG. 18, which will be described later, each of the position determining opening pattern AP1 and the position determining opening pattern AP2 is formed only in the organic insulating film OF out of the inorganic insulating film CF and the organic insulating film OF.

Here, the organic insulating film OF is more likely to shrink due to a thermal influence than the inorganic insulating film CF. Therefore, when an opening end of an opening portion OPO formed in the organic insulating film OF is defined as the outer edge (the side OPS1, the side OPS2, the side OPS3, and the side OPS4) of the main opening portion OPM illustrated in FIG. 13, the position of the outer edge of the main opening portion OPM may be misaligned due to the thermal influence.

In the present embodiment, each of the position determining opening pattern AP1 and the position determining opening pattern AP2 illustrated in FIGS. 17 and 18 is formed at least in the organic insulating film OF. However, as illustrated in FIG. 13, the opening area of each of the position determining opening pattern AP1 and the position determining opening pattern AP2 is sufficiently smaller than the opening area of the main opening portion OPM (for example, 5% or less). Therefore, even if the organic insulating film OF shrinks due to the thermal influence, the opening shapes of the position determining opening pattern AP1 and the position determining opening pattern AP2 are hardly deformed.

That is, in FIG. 13, if each of the position determining opening pattern AP1 and the position determining opening pattern AP2 is used as a mark for identifying the position of the bonding region BR, the positions of the side BRS1 and the side BRS4, which are particularly important among the sides of the bonding region BR, can be accurately identified.

Also, in the example illustrated in FIG. 13, each of the position determining opening pattern AP1 and the position determining opening pattern AP2 forms an opening pattern communicating with the main opening portion OPM. In other words, the opening portion OP1 includes the main opening portion OPM and the plurality of position determining opening patterns (the position determining opening patterns AP1 and AP2) connected to the main opening portion OPM.

The position determining opening pattern AP1 is connected to the main opening portion OPM at the corner portion OPC1 of the main opening portion OPM. The position determining opening pattern AP2 is connected to the main opening portion OPM at the corner portion OPC4 of the main opening portion OPM.

When each of the plurality of position determining opening patterns is connected to the main opening portion OPM, patterning of an opening shape is easier than the case where each of the plurality of position determining opening patterns is separated from the main opening portion OPM as illustrated in FIG. 16, which is a modification of FIG. 13.

FIG. 16 is an enlarged plan view illustrating a region around a main opening portion of a semiconductor chip, which is a modification of FIG. 13. Note that illustration of the cross line (the horizontal line 400A and the vertical line 400B) illustrated in FIG. 13 is omitted in FIG. 16.

A semiconductor chip 10A illustrated in FIG. 16 is different from the semiconductor chip 10 illustrated in FIG. 13 in that each of the position determining opening pattern AP1 and the position determining opening pattern AP2 is separated from the main opening portion OPM. Since other points are similar to those of the semiconductor chip 10 illustrated in FIG. 13, redundant description thereof is omitted.

From the viewpoint of improving the accuracy of identifying the outer edge of the bonding region BR, it is preferable that each of the position determining opening pattern AP1 and the position determining opening pattern AP2 is separated from the main opening portion OPM as in the semiconductor chip 10A. That is, when the organic insulating film OF (see FIG. 8) shrinks due to the thermal influence as described above, the main opening portion OPM may be deformed. Since each of the position determining opening pattern AP1 and the position determining opening pattern AP2 is separated from the main opening portion OPM, even when the main opening portion OPM is deformed, the position determining opening pattern AP1 and the position determining opening pattern AP2 are more unlikely to be affected by the deformation as compared with the example illustrated in FIG. 13.

Further, in the example of FIG. 13 and the example of FIG. 16, the position determining opening pattern AP1 includes the intersection between the side OPS1 and the extended line of the side OPS2. In other words, the outer side AS12 of the position determining opening pattern AP1 overlaps the extended line of the side OPS1 of the main opening portion OPM. In this case, a distance from an opening end of the main opening portion OPM to the bonding region BR can be easily recognized visually. For this reason, when the operator visually checks a product based on an image displayed on the monitor 703 (see FIG. 10) in the quality determining step illustrated in FIG. 15, the operator is unlikely to erroneously recognize the positions of the side BRS1 and the side BRS2 of the bonding region BR.

FIG. 17 is an enlarged cross-sectional view taken along line C-C of FIG. 6. FIG. 18 is an enlarged cross-sectional view illustrating a modification of FIG. 17. Although FIG. 17 is an enlarged cross-sectional view taken along line C-C of FIG. 6, since the position determining opening pattern AP1 and the position determining opening pattern AP2 illustrated in FIG. 13 have similar structures, reference characters of the position determining opening pattern AP1 and the position determining opening pattern AP2 are given in FIGS. 17 and 18.

In the example illustrated in FIG. 17, each of the position determining opening pattern AP1 and the position determining opening pattern AP2 is formed in both the inorganic insulating film CF and the organic insulating film OF. On the other hand, a semiconductor chip 10B illustrated in FIG. 18 is different from the semiconductor chip 10 in FIG. 17 in that each of the position determining opening pattern AP1 and the position determining opening pattern AP2 is formed only in the organic insulating film OF. Therefore, the source pad 10P1 is not exposed from the insulating film IF (more specifically, the inorganic insulating film CF) in the position determining opening patterns AP1 and AP2. Since the semiconductor chip 10B is similar to the semiconductor chip 10 except for the above-described differences, redundant description thereof is omitted.

Although illustration is omitted, there is a case in which each of the position determining opening pattern AP1 and the position determining opening pattern AP2 is formed only in the inorganic insulating film CF as another modification of FIG. 17. However, in this modification, when fluidity of the organic insulating film OF at a time of application is high, the organic insulating film OF may be embedded in the opening portion OPC formed in the inorganic insulating film CF. Therefore, from a viewpoint of improving a level of visibility of the image displayed on the monitor 703 (see FIG. 10), the structure of the semiconductor chip 10 illustrated in FIG. 17 or the structure of the semiconductor chip 10B illustrated in FIG. 18 is preferable.

FIG. 19 is an enlarged plan view illustrating another modification of FIG. 13. Note that illustration of the cross line (the horizontal line 400A and the vertical line 400B) illustrated in FIG. 13 is omitted in FIG. 19.

A semiconductor chip 10C illustrated in FIG. 19 is different from the semiconductor chip 10 illustrated in FIG. 13 in the following points. The plurality of position determining opening patterns of the semiconductor chip 10C includes the position determining opening pattern AP2 located between the extended line of the side OPS1 and the extended line of the side OPS4 in the Y direction and arranged at a position closest to the corner portion OPC3 among the corner portion OPC1, the corner portion OPC2, the corner portion OPC3, and the corner portion OPC4 of the main opening portion OPM. Also, the plurality of position determining opening patterns further includes a position determining opening pattern AP3 located between the extended line of the side OPS1 and the extended line of the side OPS4 in the Y direction and arranged at a position closest to the corner portion OPC2 among the corner portion OPC1, the corner portion OPC2, the corner portion OPC3, and the corner portion OPC4 of the main opening portion OPM. In addition, the plurality of position determining opening patterns further includes a position determining opening pattern AP4 located between the extended line of the side OPS1 and the extended line of the side OPS4 in the Y direction and arranged at a position closest to the corner portion OPC4 among the corner portion OPC1, the corner portion OPC2, the corner portion OPC3, and the corner portion OPC4 of the main opening portion OPM.

The bonding region BR is defined by the position determining opening pattern AP1, the position determining opening pattern AP2, the position determining opening pattern AP3, the position determining opening pattern AP4, the side OPS2, and the side OPS3.

More specifically, as illustrated in FIG. 19, in plan view, the position determining opening pattern AP3 includes an inner side AS31 extending in the X direction and an outer side AS32 extending in the X direction and arranged at a position closer to the side OPS1 than the inner side AS31 is. In plan view, the position determining opening pattern AP4 includes an inner side AS41 extending in the X direction and an outer side AS42 extending in the X direction and arranged at a position closer to the side OPS4 than the inner side AS41 is.

In the identifying step of the position of a bonding illustrated in FIG. 15, the bonding region BR is defined by a virtual line connecting the inner side AS11 of the position determining opening pattern AP1 and the inner side AS31 of the position determining opening pattern AP3, a virtual line connecting the inner side AS21 of the position determining opening pattern AP2 and the inner side AS41 of the position determining opening pattern AP4, the side OPS2, and the side OPS3.

In this modification, the position determining opening pattern is provided at each of the four corner portions of the main opening portion OPM. As a result, the visibility when the outer edge of the bonding region BR is identified from an image is further improved as compared with the example illustrated in FIG. 13.

In addition, this modification is advantageous in the following points. That is, in the example illustrated in FIG. 12, the extending portion 51L of the wire 51 extends in the direction from the side OPS2 toward the side OPS3. At this time, when the position determining opening pattern is formed at the corner portion OPC2, the position determining opening pattern may be covered with the extending portion 51L of the wire 51 depending on the bending angle of the bent portion 51C of the wire 51. In order to avoid this, the position determining opening pattern AP1 needs to be provided along the side opposite the bending direction of the wire 51 (that is, the side OPS2 in the example illustrated in FIG. 12).

On the other hand, in the example illustrated in FIG. 19, since the position determining opening pattern is provided at each of the four corner portions, at least three of the four position determining opening patterns can be visually recognized regardless of the bending direction of the wire 51.

Since the semiconductor chip 10C illustrated in FIG. 19 is similar to the semiconductor chip 10 illustrated in FIG. 13 except for the above-described differences, redundant description thereof is omitted. Although not illustrated, the semiconductor chip 10C illustrated in FIG. 19 can be applied in combination with the above-described various modifications.

For example, there is a case in which each of the four position determining opening patterns of the semiconductor chip 10C illustrated in FIG. 19 is separated from the main opening portion OPM as with the semiconductor chip 10A illustrated in FIG. 16.

In addition, for example, each of the four position determining opening patterns of the semiconductor chip 10C illustrated in FIG. 19 includes the opening portion OPC formed in the inorganic insulating film CF and the opening portion OPO formed in the organic insulating film OF as with the position determining opening patterns AP1 and d AP2 of the semiconductor chip 10 illustrated in FIG. 17. However, as a modification, there is case in which each of the four position determining opening patterns is formed only in the organic insulating film OF as with the semiconductor chip 10B illustrated in FIG. 18. Alternatively, there is a case in which the organic insulating film OF is not formed.

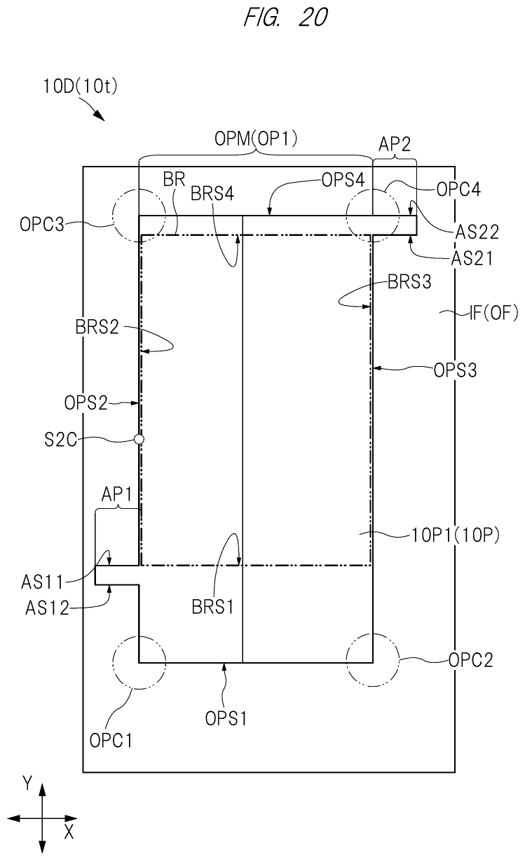

FIG. 20 is an enlarged plan view illustrating another modification of FIG. 13. Note that illustration of the cross line (the horizontal line 400A and the vertical line 400B) illustrated in FIG. 13 is omitted in FIG. 20.

A semiconductor chip 10D illustrated in FIG. 20 is different from the semiconductor chip 10 illustrated in FIG. 13 in that the position determining opening pattern AP1 is arranged between the corner portion OPC1 and a center S2C of the side OPS2. The semiconductor chip 10D is particularly effective when the area of the bonding region BR is extremely smaller than the opening area of the main opening portion OPM as illustrated in FIG. 20.

Since the position determining opening pattern AP1 is arranged between the corner portion OPC1 and the center S2C of the side OPS2, the opening area of the position determining opening pattern AP1 can be made sufficiently smaller than the opening area of the main opening portion OPM (for example, 5% or less) even when a separation distance between the bonding region BR and the side OPS1 is long.

Since the semiconductor chip 10D illustrated in FIG. 20 is similar to the semiconductor chip 10 illustrated in FIG. 13 except for the above-described differences, redundant description thereof is omitted. Note that the semiconductor chip 10D illustrated in FIG. 20 can be applied in combination with the above-described various modifications.

Further, in each of FIGS. 12, 16, 19, and 20, a rectangular pattern extending in the X direction is illustrated as an example of the shape of the position determining opening pattern. There are various modifications of the shape of the position determining opening pattern. For example, it can be square, circular, oval, or a combination of these shapes.

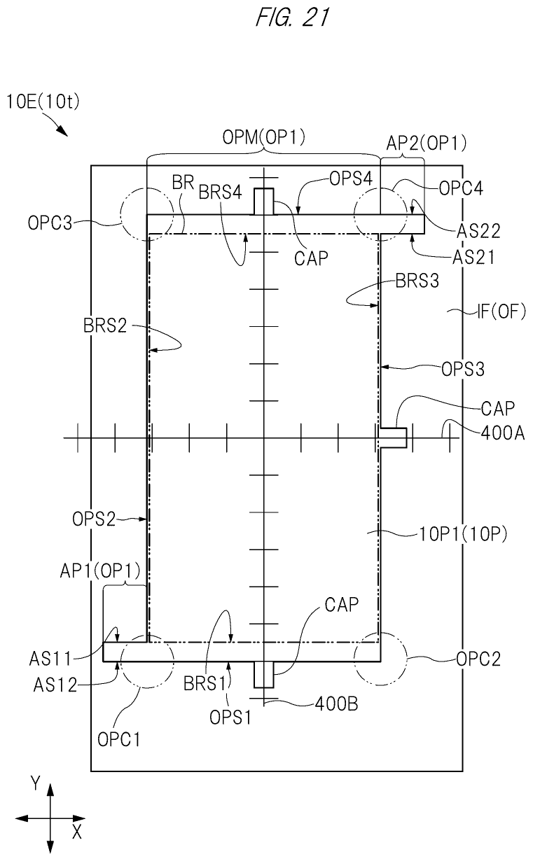

FIG. 21 is an enlarged plan view illustrating another modification of FIG. 13. A semiconductor chip 10E illustrated in FIG. 21 is different from the semiconductor chip 10 illustrated in FIG. 13 in that the semiconductor chip 10E has a mark for easily performing the above-described “teaching” in the identifying step of a bonding region illustrated in FIG. 9.

The semiconductor chip 10E has a plurality of center position identifying opening patterns CAP arranged at centers of at least three sides among the side OPS1, the side OPS2, the side OPS3, and the side OPS4 and extending in the directions perpendicular to directions in which the three sides extend.

In the identifying step of a bonding region, the position of the bonding region BR can be easily identified by superimposing the plurality of center position identifying opening patterns CAP on the cross line (the horizontal line 400A and the vertical line 400B) displayed on the monitor 703 (see FIG. 10) of the wire bonding device 700 (see FIG. 10).

Since the semiconductor chip 10E illustrated in FIG. 21 is similar to the semiconductor chip 10 illustrated in FIG. 13 except for the above-described differences, redundant description thereof is omitted. Note that the semiconductor chip 10E illustrated in FIG. 21 can be applied in combination with the above-described various modifications.

### <Modification of Quality Determining Step>

Next, a modification of the quality determining step illustrated in FIG. 4 will be described. In the above description, an embodiment in which the operator visually check a product in the quality determining step based on an image displayed on the monitor 703 illustrated in FIG. 10 has been described.

Hereinafter, a modification in which the determination unit 706 provided in the wire bonding device 700 illustrated in FIG. 10 automatically performs the quality determination will be described.

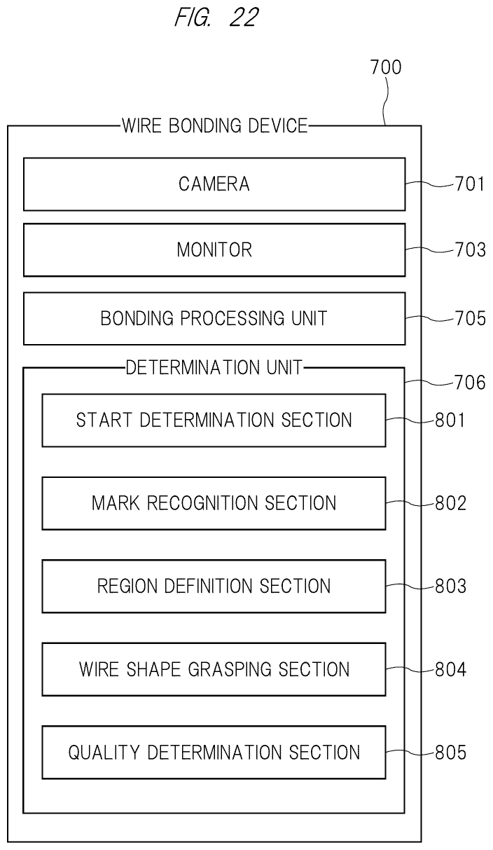

FIG. 22 is a block diagram illustrating a configuration example of the determination unit illustrated in FIG. 10. In the example illustrated in FIG. 22, the determination unit 706 includes a start determination section 801, a mark recognition section 802, a region definition section 803, a wire shape grasping section 804, and a quality determination section 805.

The start determination section 801 is configured to be able to determine whether or not to start the quality determining step illustrated in FIG. 9. More specifically, the start determination section 801 illustrated in FIG. 22 is configured to be able to determine whether to start a determination as to whether or not a connection position of the wire 51 is within an allowable range after the bonding processing unit 705 connects the wire 51 (see FIG. 2). For example, the start determination section 801 is configured to selectively start the quality determining step after activating the wire bonding device 700 and bonding the first wire 51, after replacing the jig (for example, the wedge tool 753 illustrated in FIG. 11) attached to the wire bonding device 700 in the wire bonding step, or after changing the wire bonding conditions for performing the wire bonding in the wire bonding step.

For example, the mark recognition section 802 is configured to recognize the position determining opening pattern AP1 and the position determining opening pattern AP2 illustrated in FIG. 14 from the image captured by the camera 701 and displayed on the monitor 703 by using an image recognition technology.

The region definition section 803 illustrated in FIG. 22 is configured to define the rectangular bonding region BR, which serves as a reference of the allowable range, based on the position determining opening pattern AP1 and the position determining opening pattern AP2 illustrated in FIG. 14 recognized by the mark recognition section 802. The bonding region BR defined by the region definition section 803 may be displayed on the monitor 703 illustrated in FIG. 22.

The wire shape grasping section 804 is configured to identify the boundary between the bent portion 51C of the wire 51 and the extending portion 51L based on the image of the wire 51 of FIG. 14 displayed on the monitor 703. The wire shape grasping section 804 is configured to be able to grasp the position of the bonding portion 51B (or the end portion 51E) of the wire 51 based on data regarding the identified boundary between the bent portion 51C and the extending portion 51L.

The quality determination section 805 is configured to determine whether or not a whole of the bonding portion 51B (or the end portion 51E) of the wire 51 is located in the bonding region BR based on the bonding region BR defined by the region definition section 803 and the position of the bonding portion 51B (or the end portion 51E) of the wire 51 grasped by the wire shape grasping section 804.

Then, the quality determination section 805 is configured to determine that the bonding position of the wire 51 is acceptable (YES in the quality determining step illustrated in FIG. 15) if a whole of the bonding portion 51B (or the end portion 51E) of the wire 51 illustrated in FIG. 14 is within the bonding region BR. On the other hand, the quality determination section 805 is configured to determine that the bonding position of the wire 51 is defective if a part of the bonding portion 51B (or a part of the end portion 51E) of the wire 51 is outside the bonding region BR.

The determination result is output to the monitor 703, and a warning indicator lights up when the bonding position is determined to be defective for example. The operator who has recognized the warning indicator temporarily stops an operation performed by the wire bonding device 700 and adjusts the setting of the wire bonding device 700.

On the other hand, if the bonding position is determined to be acceptable, the next processing is started automatically or based on a command input by the operator.

For example, structural features of the semiconductor chip 10 illustrated in FIG. 12, 13, 17, or the like are included in the semiconductor chip 10 provided in the finished semiconductor device PKG1 illustrated in FIGS. 2 and 3. Therefore, although redundant description is omitted, the structural features of the semiconductor chip 10 described in <Method of manufacturing Semiconductor Device> can be considered as the structural features of the finished semiconductor device PKG1. The same applies to various modifications including the semiconductor chip 10A illustrated in FIG. 16, the semiconductor chip 10B illustrated in FIG. 18, the semiconductor chip 10C illustrated in FIG. 19, the semiconductor chip 10D illustrated in FIG. 20, and the semiconductor chip 10E illustrated in FIG. 21.

Although the invention made by the inventors of this application has been specifically described based on embodiments, it goes without saying that the present invention is not limited to the above embodiments and may be modified in various ways without departing from the gist of the present invention.

Extracted as a technical idea, the features of the semiconductor device described above can be expressed as follows.

### [Appendix 1]

A semiconductor device including:
a main surface;
a pad formed on the main surface;
an insulating film in which an opening portion for exposing a part of the pad is formed; and
a plurality of position determining opening patterns arranged in a region located around a main opening portion in plan view,
wherein the opening portion includes the main opening portion, wherein, in plan view, the main opening portion includes:
   a first side extending in a first direction;
   a second side extending in a second direction intersecting the first direction;
   a third side extending in the second direction and located on a side opposite the second side;
   a fourth side extending in the first direction and located on a side opposite the first side;
   a first corner portion including an intersection between the first side and an extended line of the second side;
   a second corner portion including an intersection between the first side and an extended line of the third side;
   a third corner portion including an intersection between the fourth side and an extended line of the second side; and
   a fourth corner portion including an intersection between the fourth side and an extended line of the third side, and
wherein, in each of the first side and the fourth side of the main opening portion, when an extended line extending in a direction from the third side toward the second side in plan view is defined as a first extended line and an extended line extending in a direction from the second side toward the third side in plan view is defined as a second extended line, the plurality of position determining opening patterns includes:
   a first position determining opening pattern located between the first extended line of the first side and the first extended line of the fourth side in the second direction and arranged at a position closest to the first corner portion among the first corner portion, the second corner portion, the third corner portion, and the fourth corner portion of the main opening portion; and
   a second position determining opening pattern located between the second extended line of the first side and the second extended line of the fourth side in the second direction and arranged at a position closest to the third corner portion or the fourth corner portion among the first corner portion, the second corner portion, the third corner portion, and the fourth corner portion of the main opening portion.

### [Appendix 2]

The semiconductor device according to Appendix 1,
wherein each of the first position determining opening pattern and the second position determining opening pattern forms an opening pattern communicating with the main opening portion.

### [Appendix 3]

The semiconductor device according to Appendix 1,
wherein the plurality of position determining opening patterns includes:
   the second position determining opening pattern located between the second extended line of the first side and the second extended line of the fourth side in the second direction and arranged at a position closest to the third corner portion among the first corner portion, the second corner portion, the third corner portion, and the fourth corner portion of the main opening portion;
   a third position determining opening pattern located between the first extended line of the first side and the first extended line of the fourth side in the second direction and arranged at a position closest to the second corner portion among the first corner portion, the second corner portion, the third corner portion, and the fourth corner portion of the main opening portion; and
   a fourth position determining opening pattern located between the second extended line of the first side and the second extended line of the fourth side in the second direction and arranged at a position closest to the fourth corner portion among the first corner portion, the second corner portion, the third corner portion, and the fourth corner portion of the main opening portion.

### [Appendix 4]

The semiconductor device according to Appendix 1,
wherein the insulating film includes:
   an inorganic insulating film formed on the main surface; and
   an organic insulating film formed on the inorganic insulating film, and
wherein each of the first position determining opening pattern and the second position determining opening pattern is formed in both the inorganic insulating film and the organic insulating film.

### [Appendix 5]

The semiconductor device according to Appendix 1,
wherein the insulating film includes:
   an inorganic insulating film formed on the main surface; and
   an organic insulating film formed on the inorganic insulating film,
wherein each of the first position determining opening pattern and the second position determining opening pattern is formed in at least the organic insulating film, and
wherein an opening area of each of the first position determining opening pattern and the second position determining opening pattern is smaller than an opening area of the main opening portion.

### [Appendix 6]

The semiconductor device according to Appendix 1, further including:
a plurality of center position identifying opening patterns arranged at centers of at least three sides among the first side, the second side, the third side, and the fourth side of the main opening portion and extending in directions perpendicular to directions in which the at least three sides extend.

### [Appendix 7]

The semiconductor device according to Appendix 1, further including:
a power transistor made up of a power MOSFET or an IGBT; and
a sense transistor for detecting a current flowing through the power transistor,
wherein the pad is a source pad of the power MOSFET or an emitter pad of the IGBT, and
wherein, when an extended line obtained by extending the second side in the first direction from the first side toward the fourth side is defined as a third extended line and an extended line obtained by extending the third side in the second direction from the first side toward the fourth side is defined as a fourth extended line in plan view,
the sense transistor is located between the third extended line and the fourth extended line in transparent plan view.

### [Appendix 8]

The semiconductor device according to Appendix 1, further including:
a wire connected to a bonding region of the pad,
wherein the wire includes:
   a first end portion including a bonding portion having a bonding surface, which is a bonding interface with the pad; and
   an extending portion connected to the first end portion, extending in a third direction intersecting each of the first direction and the second direction in plan view, and intersecting the first side of the main opening portion in plan view,
wherein the bonding region has a rectangular shape having an area smaller than an opening area of the main opening portion in plan view,
wherein the bonding region is defined by the first position determining opening pattern, the second position determining opening pattern, the second side, and the third side, and
wherein a whole of the bonding portion including the bonding portion and the bent portion is located in the bonding region in plan view.

What is claimed is:

1. A method of manufacturing a semiconductor device, the method comprising:
(a) preparing a semiconductor chip including a main surface, a pad formed on the main surface, and an insulating film formed on the main surface;
(b) bonding a wire to a bonding region of the pad, wherein the bonding region is exposed from the insulating film in an opening portion formed in the insulating film; and
(c) after the (b), determining a quality as to whether or not a bonding portion of the wire is located within the bonding region in plan view,
wherein the opening portion includes a main opening portion including the bonding region,
wherein, in plan view, the main opening portion includes:
a first side extending in a first direction;
a second side extending in a second direction intersecting the first direction;
a third side extending in the second direction and located on a side opposite the second side;
a fourth side extending in the first direction and located on a side opposite the first side;
a first corner portion including an intersection between the first side and an extended line of the second side or an intersection between the first side and the second side;
a second corner portion including an intersection between the first side and the third side or an intersection between the first side and an extended line of the third side;
a third corner portion including an intersection between the fourth side and the second side or an intersection between the fourth side and an extended line of the second side; and
a fourth corner portion including an intersection between the fourth side and an extended line of the third side or an intersection between the fourth side and the third side,
wherein the insulating film includes a plurality of position determining opening patterns arranged in a region located around the main opening portion in plan view,
wherein, in each of the first side and the fourth side of the main opening portion, when an extended line extending in a direction from the third side toward the second side in plan view is defined as a first extended line and an extended line extending in a direction from the second side toward the third side in plan view is defined as a second extended line, the plurality of position determining opening patterns includes:
a first position determining opening pattern located between the first extended line of the first side and the first extended line of the fourth side in the second direction and arranged at a position closest to the first corner portion among the first corner portion, the second corner portion, the third corner portion, and the fourth corner portion of the main opening portion; and
a second position determining opening pattern located between the second extended line of the first side and the second extended line of the fourth side in the second direction and arranged at a position closest to the third corner portion or the fourth corner portion among the first corner portion, the second corner portion, the third corner portion, and the fourth corner portion of the main opening portion,
wherein the wire includes:
a first end portion including the bonding portion having a bonding surface, which is a bonding interface with the pad; and
an extending portion connected to the first end portion, extending in a third direction intersecting each of the first direction and the second direction in plan view, and intersecting the first side of the main opening portion in plan view,
wherein the bonding region has a rectangular shape having an area smaller than an opening area of the main opening portion in plan view,
wherein the bonding region is defined by the first position determining opening pattern, the second position determining opening pattern, the second side, and the third side, and
wherein, in the (c), the quality is determined based on whether or not a whole of the bonding portion is located within the bonding region.

2. The method of manufacturing the semiconductor device according to claim 1,
wherein, in a plan view, the first position determining opening pattern includes a first inner side extending in the first direction and a first outer side extending in the first direction and arranged at a position closer to the first side than the first inner side is,
wherein, in a plan view, the second position determining opening pattern includes a second inner side extending in the first direction and a second outer side extending in the first direction and arranged at a position closer to the fourth side than the second inner side is, and
wherein the bonding region is defined by an extended line of the first inner side of the first position determining opening pattern, an extended line of the second inner side of the second position determining opening pattern, the second side, and the third side.

3. The method of manufacturing the semiconductor device according to claim 1,
wherein each of the first position determining opening pattern and the second position determining opening pattern forms an opening pattern communicating with the main opening portion.

4. The method of manufacturing the semiconductor device according to claim 1,
wherein the plurality of position determining opening patterns includes:
the second position determining opening pattern located between the second extended line of the first side and the second extended line of the fourth side in the second direction and arranged at a position closest to the third corner portion among the first corner portion, the second corner portion, the third corner portion, and the fourth corner portion of the main opening portion;
a third position determining opening pattern located between the first extended line of the first side and the first extended line of the fourth side in the second direction and arranged at a position closest to the second corner portion among the first corner portion, the second corner portion, the third corner portion, and the fourth corner portion of the main opening portion; and
a fourth position determining opening pattern located between the second extended line of the first side and the second extended line of the fourth side in the second direction and arranged at a position closest to the fourth corner portion among the first corner portion, the second corner portion, the third corner portion, and the fourth corner portion of the main opening portion, and
wherein the bonding region is defined by the first position determining opening pattern, the second position determining opening pattern, the third position determining opening pattern, the fourth position determining opening pattern, the second side, and the third side.

5. The method of manufacturing the semiconductor device according to claim 1,
wherein the insulating film includes:
an inorganic insulating film formed on the main surface; and
an organic insulating film formed on the inorganic insulating film, and
wherein each of the first position determining opening pattern and the second position determining opening pattern is formed in both the inorganic insulating film and the organic insulating film.

6. The method of manufacturing the semiconductor device according to claim 1,
wherein the insulating film includes:
an inorganic insulating film formed on the main surface; and
an organic insulating film formed on the inorganic insulating film,
wherein each of the first position determining opening pattern and the second position determining opening pattern is formed in at least the organic insulating film, and
wherein an opening area of each of the first position determining opening pattern and the second position determining opening pattern is smaller than the opening area of the main opening portion.

7. The method of manufacturing the semiconductor device according to claim 1,
wherein the insulating film includes:
an inorganic insulating film formed on the main surface; and
an organic insulating film formed on the inorganic insulating film, and
wherein each of the first position determining opening pattern and the second position determining opening pattern is formed in the organic insulating film out of the inorganic insulating film and the organic insulating film.

8. The method of manufacturing the semiconductor device according to claim 1,
wherein the (c) is selectively performed after a wire bonding device for performing the (b) is activated and a first wire is bonded, after a jig attached to the wire bonding device is replaced in the (b), or after a wire bonding condition for performing wire bonding is changed in the (b).

9. The method of manufacturing the semiconductor device according to claim 1, the method further comprising:
(d) after the (a) and before the (b), identifying the bonding region in a part of the pad, wherein the portion is exposed in the opening portion,
wherein the semiconductor chip has a plurality of center position identifying opening patterns provided at centers of at least three sides among the first side, the second side, the third side, and the fourth side and extending in directions perpendicular to directions, respectively, in which the at least three sides extend, and
wherein, in the (d), the bonding region is identified by superimposing the plurality of center position identifying opening patterns on a cross line displayed on a monitor of a wire bonding device.

10. The method of manufacturing the semiconductor device according to claim 1,
wherein the semiconductor chip includes:
a power transistor made up of a power MOSFET or an IGBT; and
a sense transistor for detecting a current flowing through the power transistor, and
wherein the pad is a source pad of the power MOSFET or an emitter pad of the IGBT.

11. The method of manufacturing the semiconductor device according to claim 10,
wherein, when an extended line obtained by extending the second side in the first direction from the first side toward the fourth side is defined as a third extended line and an extended line obtained by extending the third side in the second direction from the first side toward the fourth side is defined as a fourth extended line in plan view,
the sense transistor is located between the third extended line and the fourth extended line in transparent plan view.

12. The method of manufacturing the semiconductor device according to claim 1,
wherein, in the (b), the wire is formed so as to straddle the first side of the main opening portion in plan view.

13. The method of manufacturing the semiconductor device according to claim 1,
wherein, in the (c), the quality is determined based on whether or not the whole of the bonding portion and a whole of a first portion of the wire are located within the bonding region.

14. The method of manufacturing the semiconductor device according to claim 13,
wherein a length of the first portion in the second direction is 8% or more and 12% or less of a length of the bonding portion in the second direction.
